(19) United States
(12) Patent Application Publication
(10) Pub. No.: US 2025/0340483 A1
(43) Pub. Date: Nov. 6, 2025

(54) ION EXCHANGED GLASS-CERAMIC ARTICLES

(71) Applicant: CORNING INCORPORATED, CORNING, NY (US)

(72) Inventors: Qiang Fu, Painted Post, NY (US); Jennifer Lynn Hunt, Corning, NY (US); Rostislav Vatchev Roussev, Painted Post, NY (US); Charlene Marie Smith, Corning, NY (US); Alana Marie Whittier, Painted Post, NY (US); Taylor Marie Wilkinson, Painted Post, NY (US)

(21) Appl. No.: 19/269,357

(22) Filed: Jul. 15, 2025

Related U.S. Application Data
(62) Division of application No. 16/369,613, filed on Mar. 29, 2019, now abandoned.
(60) Provisional application No. 62/649,863, filed on Mar. 29, 2018.

(51) Int. Cl. C03C 21/00; C03C 3/097; C03C 10/00; H05K 5/03

(52) U.S. Cl. CPC C03C 21/002; C03C 3/097; C03C 10/0027; H05K 5/03

(57) ABSTRACT

Disclosed herein are glass-ceramic article having a first surface, a second surface opposing the first surface, a first region extending from the first surface to a first depth d1, and a second region extending from a depth greater than or equal to d1 to a second depth d2, wherein the second region comprises a crystalline phase and a glass phase, and wherein an area percentage % of crystals in the first region is less than an area percentage % of crystals in the second region. In some embodiments, a compressive stress layer extends from the first surface to a depth of compression (DOC), wherein the DOC is greater than or equal to 0.05 mm an average compressive stress in the first region is greater than or equal to 50 MPa. In some embodiments, the DOC is greater than d1; a reduce modulus of the first region is less than the reduced modulus of the second region; and/or a hardness of the first region is less than the hardness of the second region.

### CROSS-REFERENCE TO RELATED APPLICATION

This application is a divisional application and claims the benefit of priority under 35 U.S.C. § 120 of U.S. application Ser. No. 16/369,613 filed on Mar. 29, 2019, which in turn, claims the benefit of priority under 35 U.S.C. § 119 of U.S. Application Ser. No. 62/649,863 filed on Mar. 29, 2018, the content of which is relied upon and incorporated herein by reference in its entirety.

### FIELD

The disclosure relates to ion exchanged glass-ceramic articles, and more particularly to ion exchanged glass-ceramic articles have an outer region that has less crystals than an inner region.

### BACKGROUND

Glass-ceramic articles can be chemically strengthened, for example through ion exchange, to improve the mechanical properties such as resistance to crack penetration and drop performance. The ion exchange process in glass-ceramics, which are multiphase materials with one or more crystalline phases and a residual glass phase, can be complex. Ion exchange can affect one or more of the crystalline phases in addition to the residual glass phase. This phenomena can lead to new improvements in the mechanical properties of the glass-ceramic articles that are desired in cover substrates and housings for mobile electronic devices.

### SUMMARY

In a first aspect, a glass-ceramic article comprises a first surface; a second surface opposing the first surface; a first region extending from the first surface to a first depth d1; a second region extending from a depth greater than or equal to d1 to a second depth d2, wherein the second region comprises a crystalline phase and a glass phase; and a compressive stress layer extending from the first surface to a depth of compression (DOC), wherein an area percentage % of crystals in the first region is less than an area percentage % of crystals in the second region, wherein the DOC is greater than or equal to 0.05 mm, and wherein an average compressive stress in the first region is greater than or equal to 50 MPa.

In a second aspect, a glass-ceramic article comprises a first surface; a second surface opposing the first surface; a first region extending from the first surface to a first depth d1; a second region extending from a depth greater than or equal to d1 to a second depth d2, wherein the second region comprises a crystalline phase and a glass phase; and a compressive stress layer extending from the first surface to a depth of compression (DOC), wherein an area percentage of crystals in the first region is less than an area percentage of crystals in the second region, and wherein the DOC is greater than d1.

In a third aspect, a glass-ceramic article comprises a first surface; a second surface opposing the first surface; a first region extending from the first surface to a first depth d1; and a second region extending from a depth greater than or equal to d1 to a second depth d2, wherein the second region comprises a crystalline phase and a glass phase, wherein an area percentage of crystals in the first region is less than an area percentage of crystals in the second region, and wherein a reduced modulus of the first region is less than the reduced modulus of the second region.

In a fourth aspect, a glass-ceramic article comprises a first surface; a second surface opposing the first surface; a first region extending from the first surface to a first depth d1; and a second region extending from a depth greater than or equal to d1 to a second depth d2, wherein the second region comprises a crystalline phase and a glass phase, wherein an area percentage of crystals in the first region is less than an area percentage of crystals in the second region, and wherein a hardness of the first region is less than the hardness of the second region.

In a fifth aspect, a glass-ceramic article comprises a first surface having an average maximum scratch width of less than 155 microns when subjected to the Scratch Test at load of 5 N based on an average of 15 measurements; a second surface opposing the first surface; a first region extending from the first surface to a first depth d1; and a second region extending from a depth greater than or equal to d1 to a second depth d2, wherein the second region comprises a crystalline phase and a glass phase and wherein an area percentage of crystals in the first region is less than an area percentage of crystals in the second region.

In a sixth aspect, a glass-ceramic article comprises a first surface having an average maximum scratch width of less than 100 microns when subjected to the Scratch Test at load of 1 N based on an average of 15 measurements; a second surface opposing the first surface; a first region extending from the first surface to a first depth d1; and a second region extending from a depth greater than or equal to d1 to a second depth d2, wherein the second region comprises a crystalline phase and a glass phase and wherein an area percentage of crystals in the first region is less than an area percentage of crystals in the second region.

In a seventh aspect, a consumer electronic product comprises a housing comprising a front surface, a back surface and side surfaces; electrical components at least partially within the housing, the electrical components comprising at least a controller, a memory, and a display, the display at or adjacent the front surface of the housing; and a cover substrate disposed over the display, wherein at least one of a portion of the housing or the cover substrate comprises the glass-ceramic article of any of the preceding aspects.

In an eighth aspect, a method for ion exchanging a glass-ceramic article comprises contacting at least a first surface of a glass-ceramic article with an ion exchange medium comprising less than 0.03 wt % total of one or more lithium-containing salts; and forming a first region in the glass-ceramic article extending from the first surface to a first depth d1 during the contacting, wherein a compressive stress layer extending from the first surface to a depth of compression (DOC), wherein after forming the first region, the glass-ceramic article comprises a second region extending from a depth greater than or equal to d1 to a second depth d2, wherein the second region comprises a crystalline phase and a glass phase and wherein an area percentage of crystals in the first region is less than an area percentage of crystals in the second region.

In a ninth aspect, a method for ion exchanging a glass-ceramic article comprises contacting a surface of the glass-ceramic article to a first ion exchange medium comprising at least 0.03 wt % total of one or more lithium-containing salts; contacting the surface of the glass-ceramic article with a second ion exchange medium after contacting with the first ion exchange medium, wherein the second ion exchange medium comprises a total weight percent of lithium-containing salts less than a total weight percent of lithium-containing salts than the first ion exchange medium; and forming a first region in the glass-ceramic extending from the first surface to a first depth d1 during the contacting with the second ion exchange medium, and a compressive stress layer extending from the first surface to a depth of compression (DOC), wherein after forming the first region, the glass-ceramic article comprises a second region extending from a depth greater than or equal to d1 to a second depth d2, wherein the second region comprises a crystalline phase and a glass phase, and wherein an area percentage of crystals in the first region is less than an area percentage of crystals in the second region.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

FIG. 1 is an exemplary cross-sectional view of a strengthened glass-ceramic article;

FIG. 2 is an exemplary stress profile for a strengthened glass-ceramic article;

FIG. 3 is an exemplary cross-sectional view of a strengthened glass-ceramic article according to embodiments wherein there is a transition region;

FIG. 4A is a plan view of an exemplary electronic device incorporating any of the strengthened articles disclosed herein;

FIG. 4B is a perspective view of the exemplary electronic device of FIG. 4A;

FIG. 5 is a plot of the Na₂O and K₂O concentration profile in mol % as measured by a microprobe of various samples after ion exchange as discussed in Example 1;

FIG. 6 is an X-ray diffraction trace on an ion exchanged glass-ceramic article from Example 1;

FIG. 7 is a stress profile of various samples after ion exchange from Example 1;

FIG. 8 is a plot of reduced modulus on the y axis and vitreous layer thickness on the x action for various samples after ion exchange from Example 2;

FIG. 9 is a plot of the total area of samples with the vitrified region per kg of salt in the bath vs. the lithium poisoning at the end of the run from Example 4;

FIG. 10 shows the thickness of the vitreous region for various sets of samples ion exchanged at different conditions from Example 4;

FIG. 11 is a plot of the effective diffusion coefficient vs the wt % of LiNO₃ at the beginning of various ion exchange runs from Example 4; and

FIG. 12 shows the average compressive stress of the vitreous region for various sets of samples of various ion exchange runs from Example 4.

### DETAILED DESCRIPTION

### Definitions and Measurement Techniques

As used herein, the term “glass-ceramic” are solids prepared by controlled crystallization of a precursor glass and have one or more crystalline phases and a residual glass phase.

As used herein, a “vitreous” region or layer refers to a surface region with a lower percentage of crystals than an inner region. The vitreous region or layer can be formed through (i) the decrystallization of one or more crystalline phases of a glass-ceramic article during ion exchange, (ii) the lamination or fusing of a glass to a glass-ceramic, or (iii) other means known in the art such as formation while ceramming a precursor glass into a glass-ceramic.

As used herein, “depth of compression” or “DOC” refers to the depth of a compressive stress (CS) layer and is the depth at which the stress within a glass-ceramic article changes from compressive stress to tensile stress and has a stress value of zero. According to the convention normally used in the art, compressive stress is expressed as a negative (<0) stress and tensile stress is expressed as a positive (>0) stress. Throughout this description, however, and unless otherwise noted, CS is expressed as a positive or absolute value—that is, as recited herein, CS=|CS|.

The depth/thickness of the vitreous region can be measured by identifying the depth of precipitous change in the relative area of crystalline and non-crystalline sub-regions in a scanning electron microscopy (SEM) image of a polished cross-section of the sample including the edge formed by the original sample surface and the polished cross-section.

The reduced modulus, hardness and penetration depth can be measured using nanoindentation. In particular, the reduced modulus, hardness, and penetration depth were measured using a Bruker Hysitron TI980 instrument with a 1-dimensional, 3-plate capacitive transducer with a Berkovich geometry tip for quasistatic indentation to obtain a load-depth curve. The reduced modulus (Er), hardness (H), and penetration depth (h_f) were then calculated as described in Oliver, W.C. and G. M. Pharr: “An improved technique for determining hardness and elastic modulus using load and displacement sensing indentation experiments”, J. Mater. Res., Vol. 7, No. 6, June 1992, which is herein incorporated by reference in its entirety. The penetration depth is the final depth of the nanoindentation impression after the indenter tip is unloaded.

The maximum scratch width of the glass-ceramic articles were measured according to the following procedure, referred to herein as “the Scratch Test”. A Bruker Universal Mechanical Tester (UMT) with a Knoop tip was used to generate scratches in the samples using the following loading function: (1) start with a 0.25 N load and increasing the load at a 0.14 N/s loading rate to the maximum load, (2) then scratching the sample for 10 mm at a 5 mm/min scratch speed, and (3) then unloading at a 0.14 N/s rate to a load of 0.25 N at which point the tip is removed. A maximum load of 1 N, 3 N, and 5 N was used on each sample. After scratching, the samples were left for at least 12 hours in case there was any delayed failure of the sample. Then images of the scratched samples were taken with a Keyence VHX-5000 digital microscope at a magnification of 300×. Measurements were taken at 3 points of each scratch. The first was in the top 50% of the scratch at the widest lateral location (0-5 mm); the second was at the exact middle of the scratch (5 mm location); and the third was at in the bottom 50% of the scratch at the widest lateral location (5-10 mm). The first and third measurements varied for each scratch based on where the widest later portion of the scratch occurred. The imaging software was used to obtain the measurements and an average maximum width value in μm was calculated for each scratch based on the three measurement locations.

CS of the vitreous region is measured by the birefringence of the first transmission (coupling) resonance of the vitreous region in a prism coupling measurement and measures the depth of layer of the vitreous region by the spacing between the first and second transmission resonances or the breadth of the first transmission resonance.

The DOC and maximum central tension (CT) values are measured using a scattered light polariscope (SCALP) model number SCALP-04 available from GlasStress Ltd., located in Tallinn, Estonia.

CS present in the inner region is measured by the refracted near-field (RNF) method described in U.S. Pat. No. 8,854,623, entitled “Systems and methods for measuring a profile characteristic of a glass sample”, which is hereby incorporated by reference in its entirety. The RNF measurement is force balanced and calibrated to the maximum CT value provided by a SCALP measurement. In particular, the RNF method includes placing the glass article adjacent to a reference block, generating a polarization-switched light beam that is switched between orthogonal polarizations at a rate of between 1 Hz and 50 Hz, measuring an amount of power in the polarization-switched light beam and generating a polarization-switched reference signal, wherein the measured amounts of power in each of the orthogonal polarizations are within 50% of each other. The method further includes transmitting the polarization-switched light beam through the glass sample and reference block for different depths into the glass sample, then relaying the transmitted polarization-switched light beam to a signal photodetector using a relay optical system, with the signal photodetector generating a polarization-switched detector signal. The method also includes dividing the detector signal by the reference signal to form a normalized detector signal and determining the profile characteristic of the glass sample from the normalized detector signal.

The stress profile may be measured with a combination of (i) the birefringence of the first transmission (coupling) resonance of the vitreous region in a prism coupling measurement for the CS in the vitreous region(s); (ii) RNF for CS in the inner region; and (iii) SCALP for the CT region.

The amount of crystals in a region of an article can be measured by inspection of a high resolution scanning electron microscope (SEM) image in terms of area percentage.

The crystalline phase assemblage (before ion exchange) is determined based on x-ray diffraction (XRD) using a Rietveld analysis.

### General Overview of Properties of Glass-Ceramic Articles

Reference will now be made in detail to the present preferred embodiment(s), an examples of which is/are illustrated in the accompanying drawings. Whenever possible, the same reference numerals will be used throughout the drawings to refer to the same or like parts.

Glass-ceramic articles can be engineered through chemical strengthening, such as through ion exchange, to design or control the properties of the strengthened article. As disclosed herein, when glass-ceramic articles are subjected to certain ion exchange conditions one or more of the crystalline phases can be “decrystallized” to form a surface region or layer that has a lower area percentage of crystals than an inner region of the glass-ceramic article. In this decrystallization process one or more of the crystalline phases can be broken down by the ion exchange process. This surface region with the lower area percentage of crystals can have different properties than the inner region of the glass-ceramic article, such as differences in reduced modulus and/or hardness, which in turn can lead to the surface of the glass-ceramic article having better scratch performance than a glass-ceramic article that is ion exchanged without this surface region with a lower area percentage of crystals. The creation of this surface region can also lead to unique stress profile characteristics wherein both the surface region and a portion of the inner region are under compressive stress and the depth of the compression layer goes into the inner region. In other embodiments, these same properties can be created in a laminate where in a glass article is laminated to a glass-ceramic article.

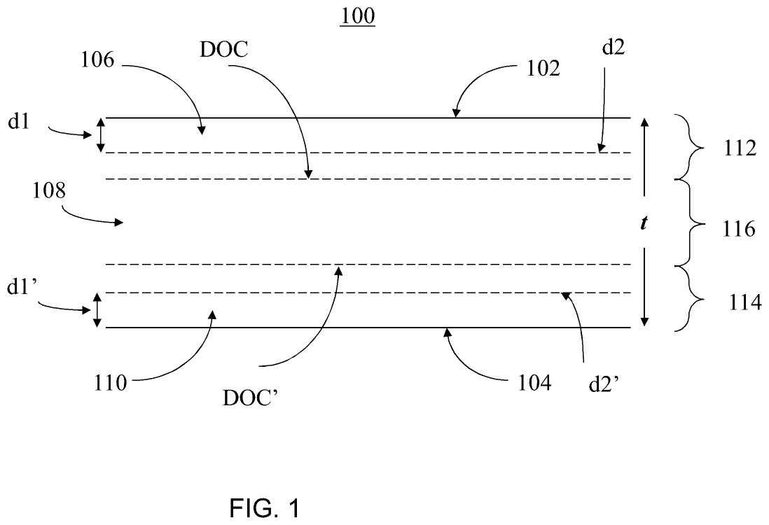

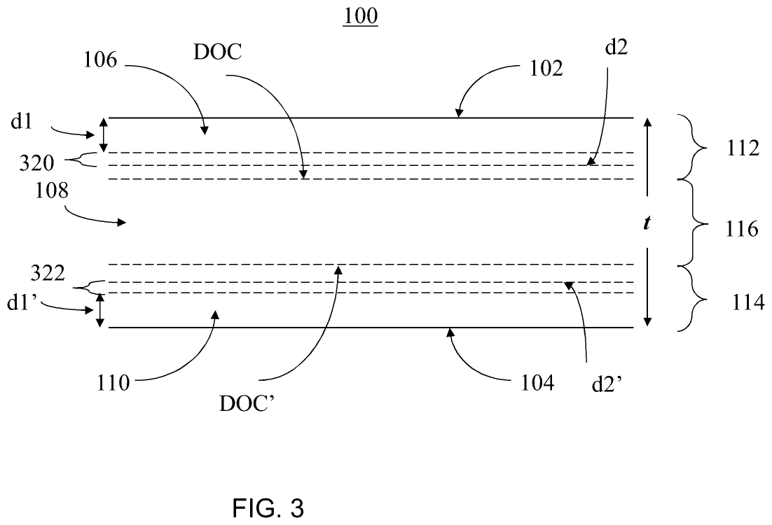

FIG. 1 depicts an exemplary cross-sectional side view of a strengthened glass-ceramic article 100 having a first surface 102 and an opposing second surface 104 separated by a thickness (t). In some embodiments, strengthened glass-ceramic article 100 has been ion exchanged and has a vitreous outer region 106 (or first region) extending from first surface 102 to a first depth d1. An inner region 108 (or second region) extends from a second depth d2 greater than or equal to first depth d1. In some embodiments, strengthened glass-ceramic article 100 also has a vitreous outer region 110 (or third region) extending from second surface 104 to a third depth d1′. In embodiments where strengthened glass-ceramic article 100 has vitreous outer regions 106 and 110, inner region 108 extends from second depth d2 to a fourth depth d2′, wherein fourth depth d2′ is measured from second surface 104 and is greater than or equal to third depth d1′. First depth d1 of vitreous outer region 106 and third depth d1′ of vitreous outer region 110 can be equal or different. Similarly second depth d2 and fourth depth d2′ can be equal or different. In some embodiments, the strengthened glass-ceramic article has only a single vitreous outer region 106, and in such instances, inner region 108 extends from second depth d2 to second surface 104. FIG. 1 illustrates an embodiment wherein d1 equals d2 and d1′ equals d2′, but this is merely exemplary. In other embodiments, as discussed below with respect to FIG. 3, d2 is greater than d1 and/or d2′ is greater than d1′.

In some embodiments, vitreous outer regions 106 and/or 110 may have a lower area percentage of crystals than inner region 108 of the glass-ceramic article 100 as determined by SEM imaging as discussed above. For example the vitreous outer regions may have an area percentage of crystals in a range from 0% to 15%, 0% to 12%, 0% to 10%, 0% to 8%, 0% to 5%, 0% to 2%, 2% to 15%, 2% to 12%, 2% to 10%, 2% to 8%, 2% to 5%, 5% to 15%, 5% to 12%, 5% to 10%, 5% to 8%, 8% to 15%, 8% to 12%, 8% to 10%, 10% to 15%, 10% to 12%, 12% to 15%, and any ranges or subranges therebetween. In some embodiments, the vitreous outer regions may have an area percentage of crystals of less than or equal to 15%, 10%, or 5%.

Strengthened glass-ceramic article 100 also has a compressive stress (CS) layer 112 extending from first surface 102 to a depth of compression (DOC). In some embodiments, as shown in FIG. 1, the DOC is greater than first depth d1 of vitreous outer region 106 such that vitreous outer region 106 and a portion of inner region 108 is under compressive stress and that the DOC is located in inner region 108. In other embodiments, DOC may be less than or equal to first depth d1 of vitreous outer region 106. In some embodiments, as shown in FIG. 1, the glass-ceramic article 100 also has a compressive stress (CS) layer 114 extending from second surface 104 to a depth of compression DOC′. There is also a central tension region 116 under tensile stress in between DOC and DOC′. In some embodiments, as shown in FIG. 1, the DOC′ is greater than third depth d1′ of vitreous outer region 110 such that vitreous outer region 110 and a portion of inner region 108 is under compressive stress and that the DOC′ is located in inner region 108. In other embodiments, DOC′ may be less than or equal to third depth d1′ of vitreous outer region 110.

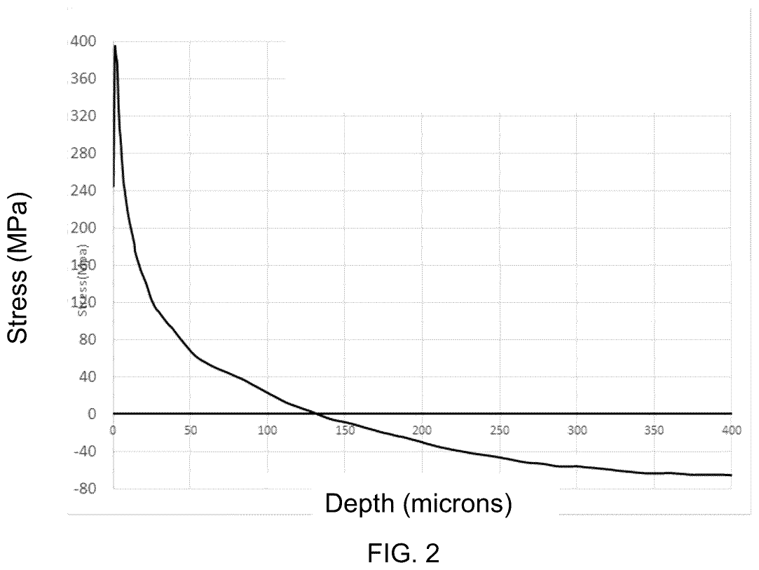

FIG. 2 illustrates an exemplary stress profile for the first half of the thickness (0.5*t) for glass-ceramic article 100. The x-axis represents the stress value (with positive stress being compressive stress and negative stress being tensile stress and the y-axis represents the depth within the glass-ceramic article as measured from first surface 102. As can be seen in FIG. 2, in some embodiments the stress profile can have a buried CS (maximum CS) below first and/or second surfaces 102, 104 and the stress profile from buried peak to buried peak can be described as quasi-parabolic.

In some embodiments, as shown in FIG. 2, the maximum CS can be below first surface 102 and/or second surface 104. While in other embodiments, the maximum CS may be at first surface and/or second surface 104. In some embodiments, the maximum CS and/or average CS in first CS layer 112 may be different than the maximum CS and/or average CS in second CS layer 114. In other embodiments, the maximum CS can be located below first surface 102 and/or second surface 104. In some embodiments, the maximum CS for first CS layer 112 and/or second CS layer 114 may be located 0.1 to 25 microns, 0.1 to 20 microns, 0.1 to 15 microns, 0.1 to 10 microns, 0.1 to 5 microns, 0.5 to 25 microns, 0.5 to 20 microns, 0.5 to 15 microns, 0.5 to 10 microns, 0.5 to 5 microns, 1 to 25 microns, 1 to 20 microns, 1 to 15 microns, 1 to 10 microns, 1 to 5 microns, 5 to 25 microns, 5 to 20 microns, 5 to 15 microns, 5 to 10 microns, and any ranges or subranges therebetween from respective first and second surfaces 102, 104. In some embodiments, the maximum CS for first CS layer 112 and/or second CS layer 114 may be in respective vitreous outer region 106/110 In some embodiments, the average CS in vitreous outer regions 106, 110 can be in a range from 50 MPa to 1500 MPa, 50 MPa to 1250 MPa, 50 MPa to 1000 MPa, 50 MPa to 900 MPa, 50 MPa to 800 MPa, 50 MPa to 700 MPa, 50 MPa to 600 MPa, 50 MPa to 500 MPa, 50 MPa to 400 MPa, 50 MPa to 300 MPa, 50 MPa to 200 MPa, 100 MPa to 1500 MPa, 100 MPa to 1250 MPa, 100 MPa to 1000 MPa, 100 MPa to 900 MPa, 100 MPa to 800 MPa, 100 MPa to 700 MPa, 100 MPa to 600 MPa, 100 MPa to 500 MPa, 100 MPa to 400 MPa, 100 MPa to 300 MPa, 100 MPa to 200 MPa, 200 MPa to 1500 MPa, 200 MPa to 1250 MPa, 200 MPa to 1000 MPa, 200 MPa to 900 MPa, 200 MPa to 800 MPa, 200 MPa to 700 MPa, 200 MPa to 600 MPa, 200 MPa to 500 MPa, 200 MPa to 400 MPa, 300 MPa to 1500 MPa, 300 MPa to 1250 MPa, 300 MPa to 1000 MPa, 300 MPa to 900 MPa, 300 MPa to 800 MPa, 300 MPa to 700 MPa, 300 MPa to 600 MPa, 400 MPa to 1500 MPa, 400 MPa to 1250 MPa, 400 MPa to 1000 MPa, 400 MPa to 900 MPa, 400 MPa to 800 MPa, 400 MPa to 700 MPa, and any ranges and subranges therebetween, In some embodiments, the average CS in vitreous outer regions is greater than or equal to 50 MPa, 100 MPa, 200 MPa, 300 MPa, 400 MPa, 500 MPa, 600 MPa, 700 MPa, 800 MPa, 900 MPa, 1000 MPa, 1250 MPa or 1500 MPa.

As noted above, DOC and/or DOC′ may be present in inner region 108 (stated another way, first and/or second CS layers 112, 114 may extend into inner region 108). In such embodiments, inner region 108 may have a maximum compressive stress greater than or equal to 10 MPa, 20 MPa or 30 MPa at least 5 microns into the inner region. In some embodiments, first and/or second CS layers 112, 114 may extend past vitreous region regions 106, 110 and into inner region 108 in a range from greater than 0*t to 0.3*t, 0*t to 0.25*t, 0*t to 0.2*t, 0*t to 0.15*t, 0*t to 0.1*t. 0*t to 0.05*t. 0.05*t to 0.3*t, 0.05*t to 0.25*t, 0.05*t to 0.2*t, 0.05*t to 0.15*t, 0.05*t to 0.1*t, 0.1*t to 0.3*t, 0.1*t to 0.25*t, 0.1*t to 0.2*t, 0.1*t to 0.15*t, and all ranges and subranges therebetween wherein t is the thickness of the glass ceramic article 100.

In some embodiments, the maximum CT is in a range from 10 MPa to 170/Vt, wherein t is the thickness of the glass-ceramic article in millimeters. In some embodiments, the maximum CT is greater than or equal to 10 MPa, 20 MPa, 30 MPa, 40 MPa, 50 MPa, 60 MPa, 70 MPa, 80 MPa, 90 MPa, 100 MPa, 110 MPa, 120 MPa, 130 MPa, 140 MPa, or 150 MPa. In some embodiments, the maximum CT can be in a range from 10 MPa to 150 MPa, 10 MPa to 100 MPa, 10 MPa to 90 MPa, 10 MPa to 80 MPa, 10 MPa to 70 MPa, 20 MPa to 150 MPa, 20 MPa to 100 MPa, 20 MPa to 90 MPa, 20 MPa to 80 MPa, 20 MPa to 70 MPa, 30 MPa to 150 MPa, 30 MPa to 100 MPa, 30 MPa to 90 MPa, 30 MPa to 80 MPa, 30 MPa to 70 MPa, 40 MPa to 150 MPa, 40 MPa to 100 MPa, 40 MPa to 90 MPa, 40 MPa to 80 MPa, 40 MPa to 70 MPa, 50 MPa to 150 MPa, 50 MPa to 100 MPa, 50 MPa to 90 MPa, 50 MPa to 80 MPa, 50 MPa to 70 MPa or any range and subranges therebetween.

In some embodiments, the depth of a compressive stress layer, for example DOC and/or DOC′ is greater than the depth of the vitreous outer regions d1, d1′. In some embodiments, the depth of a compressive stress layer, for example DOC and/or DOC′ is in a range from 0.05*t to 0.3*t, 0.05*t to 0.25*t, 0.05*t to 0.2*t, 0.05*t to 0.15*t, 0.05*t to 0.1*t, 0.1*t to 0.3*t, 0.1*t to 0.25*t, 0.1*t to 0.2*t, 0.1*t to 0.15*t, 0.15*t to 0.3*t, 0.15*t to 0.25*t, 0.15*t to 0.2*t, and all ranges and subranges therebetween wherein t is the thickness of the glass ceramic article. For example, the depth of a compressive stress layer can be greater than 0.05*t, 0.06*t, 0.07*t, 0.08*t, 0.09*t, 0.1*t, 0.11*t, 0.12*t, 0.13*t, 0.14*t, 0.15*t, 0.16*t, 0.17*t, 0.18*t, 0.19*t, 0.2*t, 0.21*t, 0.22*t, 0.23*t, 0.24*t, 0.25*t, 0.26*t, 0.27*t, 0.28*t, 0.29*t, or 0.3*t. In other embodiments, the depth of a compressive stress layer is in a range from 0.05 mm to 0.6 mm, 0.05 mm to 0.5 mm, 0.05 mm to 0.4 mm, 0.05 mm to 0.3 mm, 0.05 mm to 0.2 mm, 0.05 mm to 0.1 mm, 0.1 mm to 0.6 mm, 0.1 mm to 0.5 mm, 0.1 mm to 0.4 mm, 0.1 mm to 0.3 mm, 0.2 mm to 0.6 mm, 0.2 mm to 0.5 mm, 0.2 mm to 0.4 mm, and all ranges and subranges therebetween. In some embodiments the depth of the compressive stress layer is greater than or equal to 0.05 mm, 0.06 mm, 0.07 mm, 0.08 mm. 0.09 mm, 0.1 mm. 0.15 mm, 0.2 mm, 0.25 mm, 0.3 mm, 0.35 mm, 0.4 mm. 0.45 mm, 0.5 mm, 0.55 mm or 0.6 mm.

In some embodiments, a vitreous outer region (for example 106, 110) may have a thickness in a range from about 100 nm to 25 μm, 100 nm to 20 μm, 100 nm to 15 μm, 100 nm to 10 μm, 100 nm to 5 μm, 500 nm to 25 μm, 500 nm to 20 μm, 500 nm to 15 μm, 500 nm to 10 μm, 500 nm to 5 μm, 1 μm to 25 μm, 1 μm to 20 μm, 1 μm to 15 μm, 1 μm to 10 μm, 1 μm to 5 μm, 1 μm to 4 μm, 1 μm to 3 μm, 2 μm to 25 μm, 2 μm to 20 μm, 2 μm to 15 μm, 2 μm to 10 μm, 2 μm to 5 μm, 2 μm to 4 μm, 3 μm to 25 μm, 3 μm to 20 μm, 3 μm to 15 μm, 3 μm to 10 μm, 3 μm to 5 μm, 5 μm to 25 μm, 5 μm to 20 μm, 5 μm to 15 μm, 5 μm to 10 μm, and all ranges and subranges therebetween. In some embodiments, a vitreous outer region may have a thickness of greater than or equal to 100 nm, 200 nm, 300 nm, 400 nm, 500 nm, 600 nm, 700 nm, 800 nm, 900 nm, 1 μm, 1.5 μm, 2 μm, 2.5 μm, 3 μm, 3.5 μm, 4 μm, 4.5 μm, 5 μm, 10 μm, 15 μm, or 20 μm.

In some embodiments, vitreous outer region(s) may transition into the inner region. For example, vitreous outer region(s) may be characterized as having (i) a substantially uniform area percentage of crystals and/or substantially uniform lithium ion concentration and/or (ii) a gradient of increasing crystals and/or lithium ion concentration with increase in depth from the surface with a first average slope The transition region may be characterized as having a gradient of area percentage of crystals and/or lithium ion concentration, wherein the area percentage of crystals and/or lithium ion concentration increases from the vitreous outer region(s) to the inner region with a second average slope having a larger absolute value than the absolute value of the first average slope of the vitreous outer region(s). The inner region may be characterized as having (i) at least a portion with a substantially uniform area percentage of crystals and/or lithium ion concentration and/or (ii) a portion with a gradient of increasing crystals and/or lithium ion concentration with increase in depth from the surface with a third average slope, wherein the absolute value of the second average slope of the transition region is larger than the absolute value of the average third slope of the inner region. In some embodiments, the absolute value of the average second slope of the transition region is at least 3 times the absolute value of the average first slope of the vitreous region(s) and/or the absolute value of the average third slope of the inner region. In some embodiments, a transition region may be formed when the vitreous outer regions are formed through the decrystallization of one or more crystalline phases of a glass-ceramic article during ion exchange. In some embodiments, the transition region may have a depth in a range from greater than 0 μm to 40 μm, greater than 0 μm to 35 μm, greater than 0 μm to 30 μm, greater than 0 μm to 25 μm, greater than 0 μm to 20 μm, greater than 0 μm to 15 μm, greater than 0 μm to 10 μm, 5 μm to 40 μm, 5 μm to 35 μm, 5 μm to 30 μm, 5 μm to 25 μm, 5 μm to 20 μm, 5 μm to 15 μm, 5 μm to 10 μm, 10 μm to 40 μm, 10 μm to 35 μm, 10 μm to 30 μm, 10 μm to 25 μm, 10 μm to 20 μm, and all ranges and subranges therebetween.

FIG. 3 is an exemplary illustration of strengthened glass-ceramic article 100 with a transition region 320 between vitreous outer region 106 and inner region 108 and a transition region 322 between vitreous outer region 110 and inner region 108. As shown in FIG. 3, in some embodiments where there are transition regions 320 and 322, the inner region is defined by the thickness between d2 and d2′, d2 is greater than d1 and d2′ is greater than d1′, transition region 320 is defined by the thickness between d1 and d2, and transition region 322 is defined by the thickness between d1′ and d2′. FIG. 3 is merely exemplary, and as noted above it is possible that there is only a single vitreous outer region and there is a transition region between the single vitreous outer region and the inner region. In other embodiments, there may be first and second vitreous outer regions as shown in FIG. 3, but there is only a single transition region (either 320 or 322). In some embodiments, for example when the vitreous outer layer is formed through the lamination or fusing of a glass to a glass-ceramic, the transition between the vitreous outer region(s) and the inner region is a transition point rather than a transition region.

In some embodiments, the reduced modulus of the vitreous outer region(s) is less than reduced modulus of the inner region. In some embodiments, the reduced modulus of the vitreous outer region(s) is in a range from 5% to 30%, 5% to 25%, 5% to 20%, 5% to 15%, 5% to 10%, 10% to 30%, 10% to 25%, 10% to 20%, 10% to 15%, 15% to 30%, 15% to 25%, 15% to 20%, and any ranges and subranges therebetween less than the reduced modulus of the inner region. In some embodiments, the reduced modulus of the vitreous outer region(s) is 5%, 10%, 15%, 20%, 25%, or 30% less than the reduced modulus of the inner region. It is believed that the lower reduced modulus for the vitreous outer region(s) improves the scratch performance of the glass-ceramic article, as shown in more detail in Example 2 below. Reduced modulus is measured according to the nanoindentation procedure described above. Reduced modulus is related to Young's modulus and the reduced modulus can be converted into Young's modulus based on the following relationship: 1/Eᵣ=[(1-v²)/E]+ [(1-vᵢ²)/Eᵢ] wherein Eᵣ is the reduced modulus, E is the Young's modulus, v is Poisson's ratio, Eᵢ is the Young's modulus of the nanoindenter, and vᵢ is Poisson's ratio of the nanoindenter.

In some embodiments, the hardness of the vitreous outer region(s) is less than hardness of the inner region. In some embodiments, the hardness of the vitreous outer region(s) is in a range from 5% to 30%, 5% to 25%, 5% to 20%, 5% to 15%, 5% to 10%, 10% to 30%, 10% to 25%, 10% to 20%, 10% to 15%, 15% to 30%, 15% to 25%, 15% to 20%, and any ranges and subranges therebetween less than the hardness of the inner region. In some embodiments, the hardness of the vitreous outer region(s) is 5%, 10%, 15%, 20%, 25%, or 30% less than the hardness of the inner region. It is believed that the lower hardness for the vitreous outer region(s) improves the scratch performance of the glass-ceramic article, as shown in more detail in Example 2 below. Hardness is measured according to the nanoindentation procedure described above

In some embodiments, the average maximum scratch width of the glass-ceramic articles at a load of 5 N based on an average of 15 scratches as measured by the Scratch Test described above is less than or equal to 155 μm, 150 μm, 145 μm, 140 μm, 135 μm, 130 μm, 125 μm, 120 μm, 115 μm, 110 μm, 105 μm, 100 μm, 95 μm, or 90 μm. In some embodiments, the average maximum scratch width of the glass-ceramic articles at a load of 3 N based on an average of 15 scratches as measured by the Scratch Test is less than or equal to 150 μm, 145 μm, 140 μm, 135 μm, 130 μm, 125 μm, 120 μm, 115 μm, 110 μm, 105 μm, 100 μm, 95 μm, 90 μm, 85 μm, or 80 μm. In some embodiments, the average maximum scratch width of the glass-ceramic articles at a load of IN based on an average of 15 scratches as measured by the Scratch Test is less than or equal to 100 μm, 90 μm, 80 μm, 70 μm, 60 μm 50 μm, 45 μm, 40 μm, 35 μm, 30 μm, 25 μm, or 20 μm. As noted above, it is believed that the lower hardness and/or lower reduced modulus of the vitreous outer region(s) in comparison to the inner region contributes to an improved scratch resistance in terms of average maximum scratch width for the glass-ceramic articles as shown in Example 2 below. In some embodiments, as the load is increased for the Scratch Test, the average maximum scratch width increase by no more than a factor of 3, or by no more than a factor of 2.

In some embodiments, the glass-ceramic article is transparent in that it has an average transmittance of 85% or greater, 86% or greater, 87% or greater, 88% or greater, 89% or greater, 90% or greater, 91% or greater, 92% or greater, 93% or greater (including surface reflection losses) of light over the wavelength range from 450 nm to 600 nm for a glass-ceramic article having a thickness of 1 mm. In other embodiments, glass-ceramic may be translucent over the wavelength range from 450 nm to 600 nm. In some embodiments a translucent glass-ceramic can have an average transmittance in a range from about 20% to less than about 85% of light over the wavelength range of about 450 nm to about 600 nm for a glass-ceramic article having a thickness of 1 mm. In some embodiments, vitreous outer regions 106, 110 have a lower refractive index than inner region 108.

In some embodiments, one or more of the above properties may be different with respect to the first and second surfaces 102, 104. For example, the stress profile of the glass-ceramic article may be asymmetric, for example (i) the compressive stress at the first and second surfaces 102, 104 may differ from each other by greater than or equal to 5%, 10%, 15%, 20% or 25%; (ii) the depth of the compressive stress layer measured from the first and second surface 102, 104 may differ from each other by than or equal to 5%, 10%, 15%, 20% or 25%; (iii) the average compressive stress in each of the vitreous outer regions may differ from each other by greater than or equal to 5%, 10%, 15%, 20% or 25%; and/or (iv) the thickness of the vitreous outer regions may differ from each other by greater than or equal to 5%, 10%, 15%, 20% or 25%. In addition to, or instead of having an asymmetric stress profile, the reduced modulus, hardness, and/or maximum scratch width at IN, 3N, and/or 5N loads may be different at the first and second surfaces 102, 104 by greater than or equal to 5%, 10%, 15%, 20% or 25%.

In some embodiments, the glass-ceramic article has a thickness t in a range from 0.2 mm to 4 mm, 0.2 mm to 3 mm, 0.2 mm to 2 mm, 0.2 mm to 1.5 mm, 0.2 mm to 1 mm, 0.2 mm to 0.9 mm, 0.2 mm to 0.8 mm, 0.2 mm to 0.7 mm, 0.2 mm to 0.6 mm, 0.2 mm to 0.5 mm, 0.3 mm to 4 mm, 0.3 mm to 3 mm, 0.3 mm to 2 mm, 0.3 mm to 1.5 mm, 0.3 mm to 1 mm, 0.3 mm to 0.9 mm, 0.3 mm to 0.8 mm, 0.3 mm to 0.7 mm, 0.3 mm to 0.6 mm, 0.3 mm to 0.5 mm, 0.4 mm to 4 mm, 0.4 mm to 3 mm, 0.4 mm to 2 mm, 0.4 mm to 1.5 mm, 0.4 mm to 1 mm, 0.4 mm to 0.9 mm, 0.4 mm to 0.8 mm, 0.4 mm to 0.7 mm, 0.4 mm to 0.6 mm, 0.5 mm to 4 mm, 0.5 mm to 3 mm, 0.5 mm to 2 mm, 0.5 mm to 1.5 mm, 0.5 mm to 1 mm, 0.5 mm to 0.9 mm, 0.5 mm to 0.8 mm, 0.5 mm to 0.7 mm, 0.8 mm to 4 mm, 0.8 mm to 3 mm, 0.8 mm to 2 mm, 0.8 mm to 1.5 mm, 0.8 mm to 1 mm, 1 mm to 2 mm, 1 mm to 1.5 mm, and all ranges and subranges therebetween. In some embodiments, the glass-ceramic article may be substantially planar and flat. In other embodiments, the glass-ceramic article may be shaped, for example it may have a 2.5D or 3D shape. In some embodiments, the glass-ceramic article may have a uniform thickness and in other embodiments, the glass-ceramic article may not have a uniform thickness.

In some embodiments, the glass-ceramic articles disclosed herein may be a laminate. In such embodiments, vitreous region(s) may be a glass layer and the inner region may be a glass-ceramic. The glass may be any suitable glass that is ion-exchangeable, for example a glass containing alkali metal ions. In such embodiments, the vitreous region(s) have a zero (0) area percentage of crystals. The glass and glass-ceramic layers may be laminated together through conventional means. In some embodiments, lamination can include fusing the layers together. In other embodiments, lamination excludes layers that are fused together. In some embodiments, the layers may be ion-exchanged first and then laminated. In other embodiments, the ion exchange may occur after lamination.

### Compositions

The precursor glasses and glass-ceramics described herein may be generically described as lithium-containing aluminosilicate glasses or glass-ceramics and comprise SiO₂, Al₂O₃, and Li₂O. In addition to SiO₂, Al₂O₃, and Li₂O, the glasses and glass-ceramics embodied herein may further contain alkali salts, such as Na₂O, K₂O, Rb₂O, or Cs₂O, as well as P₂O₅, and ZrO₂ and a number of other components as described below. In some embodiments, the precursor glass (before ceramming) and/or the glass-ceramic (after ceramming) may have the following composition in weight percentage on an oxide basis:
SiO₂: 55-80%;
Al₂O₃: 2-20%;
Li₂O: 5-20%;
B₂O₃: 0-10%;
Na₂O: 0-5%;
ZnO: 0-10%;
P₂O₅: 0.5-6%; and
ZrO₂: 0.2-15%.

In some embodiments, the precursor glass and/or the glass-ceramic has a composition further comprising the following optional additional components in weight percentage on an oxide basis:
K₂O: 0-4%;
MgO: 0-8%;
TiO₂: 0-5%;
CeO₂: 0-0.4% and
SnO₂: 0.05-0.5%.

Exemplary precursor glass and glass-ceramic compositions in wt % on a metal oxide basis, are listed in Table 1 below.

| Composition | 1 | 2 | 1 | 2 | 3 | 4 | 5 | 6 |
|---|---|---|---|---|---|---|---|---|
| SiO₂ (wt %) | 73.47 | 74 | 78.3 | 78.3 | 78.3 | 78.3 | 78.3 | 78.3 |
| Al₂O₃ (wt %) | 7.51 | 7.6 | 7.5 | 8.1 | 8.7 | 8.1 | 8.1 | 8.1 |
| B₂O₃ (wt %) | 0.0 | 0.0 | 0.0 | 0.2 | 0.4 | 1.0 | 2.0 | 4.0 |
| Li₂O (wt %) | 11.1 | 11.5 | 12.5 | 11.9 | 11.3 | 11.9 | 11.9 | 11.9 |
| Na₂O (wt %) | 1.63 | 0.0 | 1.7 | 1.7 | 1.7 | 1.7 | 1.7 | 1.7 |
| K₂O (wt %) | 0.0 | 0.0 | 0.0 | 0.0 | 0.0 | 0.0 | 0.0 | 0.0 |
| ZnO (wt %) | 0.0 | 0.0 | 0.0 | 0.0 | 0.0 | 0.0 | 0.0 | 0.0 |
| ZrO₂ (wt %) | 3.55 | 4.2 | 4.0 | 4.0 | 4.0 | 4.0 | 4.0 | 4.0 |
| P₂O₅ (wt %) | 2.14 | 2.1 | 2.0 | 2.2 | 2.4 | 2.2 | 2.2 | 2.2 |
| SnO₂ (wt %) | 0.22 | 0.2 | 0.0 | 0.0 | 0.0 | 0.0 | 0.0 | 0.0 |
| Composition | 7 | 8 | 9 | 10 | 11 | 12 | 13 | 14 |
| SiO₂ (wt %) | 78.3 | 78.3 | 76.3 | 74.3 | 72.3 | 70.3 | 78.3 | 78.3 |
| Al₂O₃ (wt %) | 8.1 | 8.1 | 10.1 | 12.1 | 14.1 | 16.1 | 8.1 | 8.1 |
| B₂O₃ (wt %) | 5.0 | 6.0 | 0.2 | 0.2 | 0.2 | 0.2 | 2.0 | 2.0 |
| Li₂O (wt %) | 11.9 | 11.9 | 11.9 | 11.9 | 11.9 | 11.9 | 11.9 | 11.9 |
| Na₂O (wt %) | 1.7 | 1.7 | 1.7 | 1.7 | 1.7 | 1.7 | 0.0 | 0.0 |
| K₂O (wt %) | 0.0 | 0.0 | 0.0 | 0.0 | 0.0 | 0.0 | 1.5 | 3.0 |
| ZnO (wt %) | 0.0 | 0.0 | 0.0 | 0.0 | 0.0 | 0.0 | 0.0 | 0.0 |
| ZrO₂ (wt %) | 4.0 | 4.0 | 4.0 | 4.0 | 4.0 | 4.0 | 4.0 | 4.0 |
| P₂O₅ (wt %) | 2.2 | 2.2 | 2.2 | 2.2 | 2.2 | 2.2 | 2.2 | 2.2 |
| SnO2 (wt %) | 0.0 | 0.0 | 0.0 | 0.0 | 0.0 | 0.0 | 0.0 | 0.0 |

| Composition | 15 | 16 |
|---|---|---|
| SiO₂ (wt %) | 78.3 | 78.3 |
| Al₂O₃ (wt %) | 8.1 | 8.1 |
| B₂O₃ (wt %) | 2.0 | 2.0 |
| Li₂O (wt %) | 11.9 | 11.9 |
| Na₂O (wt %) | 0.0 | 0.0 |
| K₂O (wt %) | 0.0 | 0.0 |
| ZnO (wt %) | 1.5 | 3.0 |
| ZrO₂ (wt %) | 4.0 | 4.0 |
| P₂O₅ (wt %) | 2.2 | 2.2 |
| SnO2 (wt %) | 0.0 | 0.0 |

SiO₂, an oxide involved in the formation of glass, can function to stabilize the networking structure of glasses and glass-ceramics. In some embodiments, the glass or glass-ceramic composition comprises from about 55 to about 80 wt % SiO₂. In some embodiments, the glass or glass-ceramic composition comprises from 69 to about 80 wt % SiO₂. In some embodiments, the glass or glass-ceramic composition can comprise from about 55 to about 80 wt %, about 55 to about 77 wt %, about 55 to about 75 wt %, about 55 to about 73 wt %, 60 to about 80 wt %, about 60 to about 77 wt %, about 60 to about 75 wt %, about 60 to about 73 wt %, 65 to about 80 wt %, about 65 to about 77 wt %, about 65 to about 75 wt %, about 65 to about 73 wt %, 69 to about 80 wt %, about 69 to about 77 wt %, about 69 to about 75 wt %, about 69 to about 73 wt %, about 70 to about 80 wt %, about 70 to about 77 wt %, about 70 to about 75 wt %, about 70 to about 73 wt %, about 73 to about 80 wt %, about 73 to about 77 wt %, about 73 to about 75 wt %, about 75 to about 80 wt %, about 75 to about 77 wt %, about 77 to about 80 wt %, and all ranges and subranges therebetween SiO₂. In some embodiments, the glass or glass-ceramic composition comprises about 55, 56, 57, 58, 59, 60, 61, 62, 63, 64, 65, 66, 67, 68, 69, 70, 71, 72, 73, 74, 75, 76, 77, 78, 79, or 80, wt % SiO₂.

With respect to viscosity and mechanical performance, the viscosity and mechanical performance are influenced by glass compositions. In the glasses and glass-ceramics, SiO₂ serves as the primary glass-forming oxide for the precursor glass and can function to stabilize the networking structure of glass and glass-ceramic. The amount of SiO₂ may be limited to control melting temperature (200 poise temperature), as the melting temperature of pure SiO₂ or high-SiO₂ glasses is undesirably high.

Al₂O₃ may also provide stabilization to the network and also provides improved mechanical properties and chemical durability. If the amount of Al₂O₃ is too high, however, the fraction of lithium silicate crystals may be decreased, possibly to the extent that an interlocking structure cannot be formed. The amount of Al₂O₃ can be tailored to control viscosity. Further, if the amount of Al₂O₃ is too high, the viscosity of the melt is also generally increased. In some embodiments, the glass or glass-ceramic composition can comprise from about 2 to about 20 wt % Al₂O₃. In some embodiments, the glass or glass-ceramic composition can comprise from about 6 to about 9 wt % Al₂O₃. In some embodiments, the glass or glass-ceramic composition can comprise from about 2 to about 20%, about 2 to about 18 wt %, about 2 to about 15 wt %, about 2 to about 12 wt %, about 2 to about 10 wt %, about 2 to about 9 wt %, about 2 to about 8 wt %, about 2 to about 5 wt %, about 5 to about 20%, about 5 to about 18 wt %, about 5 to about 15 wt %, about 5 to about 12 wt %, about 5 to about 10 wt %, about 5 to about 9 wt %, about 5 to about 8 wt %, about 6 to about 20%, about 6 to about 18 wt %, about 6 to about 15 wt %, about 6 to about 12 wt %, about 6 to about 10 wt %, about 6 to about 9 wt %, about 8 to about 20%, about 8 to about 18 wt %, about 8 to about 15 wt %, about 8 to about 12 wt %, about 8 to about 10 wt %, about 10 to about 20%, about 10 to about 18 wt %, about 10 to about 15 wt %, about 10 to about 12 wt %, about 12 to about 20%, about 12 to about 18 wt %, about 12 to about 15 wt %, and all ranges and subranges therebetween Al₂O₃. In some embodiments, the glass or glass-ceramic composition can comprise about 2, 3, 4, 5, 6, 7, 8, 9, 10, 11, 12, 13, 14, 15, 16, 17, 18, 19, or 20 wt % Al₂O₃.

In the glass and glass-ceramics herein, Li₂O aids in forming crystal phases. In some embodied compositions, the glass or glass-ceramic can comprise from about 5 wt % to about 20 wt % Li₂O. In other embodiments, the glass or glass-ceramic can comprise from about 10 wt % to about 14 wt % Li₂O. In some embodiments, the glass or glass-ceramic composition can comprise from about 5 to about 20 wt %, about 5 to about 18 wt %, about 5 to about 16 wt %, about 5 to about 14 wt %, about 5 to about 12 wt %, about 5 to about 10 wt %, about 5 to about 8 wt %, 7 to about 20 wt %, about 7 to about 18 wt %, about 7 to about 16 wt %, about 7 to about 14 wt %, about 7 to about 12 wt %, about 7 to about 10 wt %, 10 to about 20 wt %, about 10 to about 18 wt %, about 10 to about 16 wt %, about 10 to about 14 wt %, about 10 to about 12 wt %, 12 to about 20 wt %, about 12 to about 18 wt %, about 12 to about 16 wt %, about 12 to about 14 wt %, 14 to about 20 wt %, about 14 to about 18 wt %, about 14 to about 16 wt %, about 16 to about 20 wt %, about 16 to about 18 wt %, about 18 to about 20 wt %, and all ranges and subranges therebetween Li₂O. In some embodiments, the glass or glass-ceramic composition can comprise about 5, 6, 7, 8, 9, 10, 11, 12, 13, 14, 15, 16, 17, 18, 19, or 20 wt % Li₂O.

As noted above, Li₂O is generally useful for forming the embodied glass-ceramics, but the other alkali oxides tend to decrease glass-ceramic formation and form an aluminosilicate residual glass in the glass-ceramic. It has been found that more than about 5 wt % Na₂O or K₂O, or combinations thereof, leads to an undesirable amount of residual glass which can lead to deformation during crystallization and undesirable microstructures from a mechanical property perspective. The composition of the residual glass may be tailored to control viscosity during crystallization, minimizing deformation or undesirable thermal expansion, or control microstructure properties. Therefore, in general, the compositions described herein have low amounts of non-lithium alkali oxides. In some embodiments, the glass or glass-ceramic composition can comprise from about 0 to about 5 wt % R₂O, wherein R is one or more of the alkali cations Na and K. In some embodiments, the glass or glass-ceramic composition can comprise from about 1 to about 3 wt % R₂O, wherein R is one or more of the alkali cations Na and K. In some embodiments, the glass or glass-ceramic composition can comprise from 0 to about 5 wt %, 0 to 4 wt %, 0 to 3 wt %, 0 to about 2 wt %, 0 to about 1 wt %, >0 to about 5 wt %, >0 to about 4 wt %, >0 to about 3 wt %, >0 to about 2 wt %, >0 to about 1 wt %, about 1 to about 5 wt %, about 1 to about 4 wt %, about 1 to about 3 wt %, about 1 to about 2 wt %, about 2 to about 5 wt %, about 2 to about 4 wt %, about 2 to about 3 wt %, about 3 to about 5 wt %, about 3 to about 4 wt %, about 4 to about 5 wt %, and all ranges and subranges therebetween Na₂O or K₂O, or combinations thereof. In some embodiments, the glass or glass-ceramic composition can comprise about 0, >0, 1, 2, 3, 4, or 5 wt % R₂O.

The glass and glass-ceramic compositions can include P₂O₅. P₂O₅ can function as a nucleating agent to produce bulk nucleation. If the concentration of P₂O₅ is too low, the precursor glass does crystallize, but only at higher temperatures (due to a lower viscosity) and from the surface inward, yielding a weak and often deformed body; however, if the concentration of P₂O₅ is too high, the devitrification, upon cooling during precursor glass forming, can be difficult to control. Embodiments can comprise from >0 to about 6 wt % P₂O₅. Other embodiments can comprise about 2 to about 4 wt % P₂O₅. Still other embodiments can comprise about 1.5 to about 2.5 wt % P₂O₅. Embodied compositions can comprise from 0 to about 6 wt %, 0 to about 5.5 wt %, 0 to about 5 wt %, 0 to about 4.5 wt %, 0 to about 4 wt %, 0 to about 3.5 wt %, 0 to about 3 wt %, 0 to about 2.5 wt %, 0 to about 2 wt %, 0 to about 1.5 wt %, 0 to about 1 wt %, >0 to about 6 wt %, >0 to about 5.5 wt %, >0 to about 5 wt %, >0 to about 4.5 wt %, >0 to about 4 wt %, >0 to about 3.5 wt %, >0 to about 3 wt %, >0 to about 2.5 wt %, >0 to about 2 wt %, >0 to about 1.5 wt %, >0 to about 1 wt %, about 0.5 to about 6 wt %, about 0.5 to about 5.5 wt %, about 0.5 to about 5 wt %, about 0.5 to about 4.5 wt %, about 0.5 to about 4 wt %, about 0.5 to about 3.5 wt, about 0.5 to about 3 wt %, about 0.5 to about 2.5 wt %, about 0.5 to about 2 wt %, about 0.5 to about 1.5 wt %, about 0.5 to about 1 wt %, about 1 to about 6 wt %, about 1 to about 5.5 wt %, about 1 to about 5 wt %, about 1 to about 4.5 wt %, about 1 to about 4 wt %, about 1 to about 3.5 wt %, about 1 to about 3 wt %, about 1 to about 2.5 wt %, about 1 to about 2 wt %, about 1 to about 1.5 wt %, about 1.5 to about 6 wt %, about 1.5 to about 5.5 wt %, about 1.5 to about 5 wt %, about 1.5 to about 4.5 wt %, about 1.5 to about 4 wt %, about 1.5 to about 3.5 wt %, about 1.5 to about 3 wt %, about 1.5 to about 2.5 wt %, about 1.5 to about 2 wt %, about 2 to about 6 wt %, about 2 to about 5.5 wt %, about 2 to about 5 wt %, about 2 to about 4.5 wt %, about 2 to about 4 wt %, about 2 to about 3.5 wt %, about 2 to about 3 wt %, about 2 to about 2.5 wt %, about 2.5 to about 6 wt %, about 2.5 to about 5.5 wt %, about 2.5 to about 5 wt %, about 2.5 to about 4.5 wt %, about 2.5 to about 4 wt %, about 2.5 to about 3.5 wt %, about 2.5 to about 3 wt %, about 3 to about 6 wt %, about 3 to about 5.5 wt %, about 3 to about 5 wt %, about 3 to about 4.5 wt %, about 3 to about 4 wt %, about 3 to about 3.5 wt %, about 3.5 to about 6 wt %, about 3.5 to about 5.5 wt %, about 3.5 to about 5 wt %, about 3.5 to about 4.5 wt %, about 3.5 to about 4 wt %, about 4 to about 6 wt %, about 4 to about 5.5 wt %, about 4 to about 5 wt %, about 4 to about 4.5 wt %, about 4.5 to about 6 wt %, about 4.5 to about 5.5 wt %, about 4.5 to about 5 wt %, about 5 to about 6 wt %, about 5 to about 5.5 wt %, about 5.5 to about 6 wt %, and all ranges and subranges therebetween P₂O₅. In some embodiments, the glass or glass-ceramic composition can comprise about 0, >0, 0.5, 1, 1.5, 2, 2.5, 3, 3.5, 4, 4.5, 5, 5.5, or 6 wt % P₂O₅.

In the glass and glass-ceramics herein, it is generally found that ZrO₂ can improve the stability of Li₂O—Al₂O₃—SiO₂—P₂O₅ glass by significantly reducing glass devitrification during forming and lowering liquidus temperature. At concentrations above 8 wt %, ZrSiO₄ can form a primary liquidus phase at a high temperature, which significantly lowers liquidus viscosity. Transparent glass-ceramics can be formed when the glass contains over 2 wt % ZrO₂. The addition of ZrO₂ can also help decrease the grain size of the crystals, which aids in the formation of a transparent glass-ceramic. In some embodiments, the glass or glass-ceramic composition can comprise from about 0.2 to about 15 wt % ZrO₂. In some embodiments, the glass or glass-ceramic composition can be from about 2 to about 4 wt % ZrO₂. In some embodiments, the glass or glass-ceramic composition can comprise from about 0.2 to about 15 wt %, about 0.2 to about 12 wt %, about 0.2 to about 10 wt %, about 0.2 to about 8 wt %, about 0.2 to 6 wt %, about 0.2 to about 4 wt %, 0.5 to about 15 wt %, about 0.5 to about 12 wt %, about 0.5 to about 10 wt %, about 0.5 to about 8 wt %, about 0.5 to 6 wt %, about 0.5 to about 4 wt %, 1 to about 15 wt %, about 1 to about 12 wt %, about 1 to about 10 wt %, about 1 to about 8 wt %, about 1 to 6 wt %, about 1 to about 4 wt %, 2 to about 15 wt %, about 2 to about 12 wt %, about 2 to about 10 wt %, about 2 to about 8 wt %, about 2 to 6 wt %, about 2 to about 4 wt %, about 3 to about 15 wt %, about 3 to about 12 wt %, about 3 to about 10 wt %, about 3 to about 8 wt %, about 3 to 6 wt %, about 3 to about 4 wt %, about 4 to about 15 wt %, about 4 to about 12 wt %, about 4 to about 10 wt %, about 4 to about 8 wt %, about 4 to 6 wt %, about 8 to about 15 wt %, about 8 to about 12 wt %, about 8 to about 10 wt %, about 10 to about 15 wt %, about 10 to about 12 wt %, about 12 to about 15 wt %, and all ranges and subranges therebetween ZrO₂. In some embodiments, the glass or glass-ceramic composition can comprise about 0.2, 0.5, 1,2, 3, 4, 5, 6, 7, 8, 9, 10, 11, 12, 13, 14, or 15 wt % ZrO₂.

B₂O₃ is conducive to providing a precursor glass with a low melting temperature. Furthermore, the addition of B₂O₃ in the precursor glass and thus the glass-ceramics helps achieve an interlocking crystal microstructure and can also improve the damage resistance of the glass-ceramic. When boron in the residual glass is not charge balanced by alkali oxides or divalent cation oxides, it will be in trigonal-coordination state (or three-coordinated boron), which opens up the structure of the glass. The network around these three-coordinated boron is not as rigid as tetrahedrally coordinated (or four-coordinated) boron. Without being bound by theory, it is believed that precursor glasses and glass-ceramics that include three-coordinated boron can tolerate some degree of deformation before crack formation. By tolerating some deformation, the Vickers indentation crack initiation values are increased. Fracture toughness of the precursor glasses and glass-ceramics that include three-coordinated boron may also be increased. Without being bound by theory, it is believed that the presence of boron in the residual glass of the glass-ceramic (and precursor glass) lowers the viscosity of the residual glass (or precursor glass), which facilitates the growth of lithium silicate crystals, especially large crystals having a high aspect ratio. A greater amount of three-coordinated boron (in relation to four-coordinated boron) is believed to result in glass-ceramics that exhibit a greater Vickers indentation crack initiation load. In some embodiments, the amount of three-coordinated boron (as a percent of total B₂O₃) may be about 40% or greater, 50% or greater, 75% or greater, about 85% or greater or even about 95% or greater. The amount of boron in general should be controlled to maintain chemical durability and mechanical strength of the cerammed bulk glass-ceramic.

In one or more embodiments, the glasses and glass-ceramic herein can comprise from 0 to about 10 wt % or from 0 to about 2 wt % B₂O₃. In some embodiments, the glass or glass-ceramic composition can comprise from 0 to about 10 wt %, 0 to about 9 wt %, 0 to about 8 wt %, 0 to about 7 wt %, 0 to about 6 wt %, 0 to about 5 wt %, 0 to about 4 wt %, 0 0 to about 3 wt %, 0 to about 2 wt %, 0 to about 1 wt %, >0 to about 10 wt %, >0 to about 9 wt %, >0 to about 8 wt %, >0 to about 7 wt %, >0 to about 6 wt %, >0 to about 5 wt %, >0 to about 4 wt %, >0 to about 3 wt %, >0 to about 2 wt %, >0 to about 1 wt %, about 1 to about 10 wt %, about 1 to about 8 wt %, about 1 to about 6 wt %, about 1 to about 5 wt %, about 1 to about 4 wt %, about 1 to about 2 wt %, about 2 to about 10 wt %, about 2 to about 8 wt %, about 2 to about 6 wt %, about 2 to about 4 wt %, about 3 to about 10 wt %, about 3 to about 8 wt %, about 3 to about 6 wt %, about 3 to about 4 wt %, about 4 to about 5 wt %, about 5 wt % to about 8 wt %, about 5 wt % to about 7.5 wt %, about 5 wt % to about 6 wt %, about 5 wt % to about 5.5 wt %, and all ranges and subranges therebetween B₂O₃. In some embodiments, the glass or glass-ceramic composition can comprise about 0, >0, 1, 2, 3, 4, 5, 6, 7, 8, 9, or 10 wt % B₂O₃.

MgO can enter into the lithium aluminosilicate crystals. In one or more embodiments, the glasses and glass-ceramic herein can comprise from 0 to about 8 wt % MgO. In some embodiments, the glass or glass-ceramic composition can comprise from 0 to about 8 wt %, 0 to about 7 wt %, 0 to about 6 wt %, 0 to about 5 wt %, 0 to about 4 wt %, 0 to about 3 wt %, 0 to about 2 wt %, 0 to about 1 wt %, about 1 to about 8 wt %, about 1 to about 7 wt %, about 1 to about 6 wt %, about 1 to about 5 wt %, about 1 to about 4 wt %, about 1 to about 3 wt %, about 1 to about 2 wt %, about 2 to about 8 wt %, about 2 to about 7 wt %, about 2 to about 6 wt %, about 2 to about 5 wt %, about 2 to about 4 wt %, about 2 to about 3 wt %, about 3 to about 8 wt %, about 3 to about 7 wt %, about 3 to about 6 wt %, about 3 to about 5 wt %, about 3 to about 4 wt %, about 4 to about 8 wt %, about 4 to about 7 wt %, about 4 to about 6 wt %, about 4 to about 5 wt %, about 5 to about 8 wt %, about 5 to about 7 wt %, about 5 to about 6 wt %, about 6 to about 8 wt %, about 6 to about 7 wt %, about 7 wt % to about 8 wt %, and all ranges and subranges therebetween MgO. In some embodiments, the glass or glass-ceramic composition can comprise about 0, >0, 1, 2, 3, 4, 5, 6, 7, or 8 wt % MgO.

ZnO can enter into the lithium aluminosilicate. In one or more embodiments, the glasses and glass-ceramics herein can comprise from 0 to about 10 wt % ZnO. In some embodiments, the glass or glass-ceramic composition can comprise from 0 to about 10 wt %, 0 to about 9 wt %, 0 to about 8 wt %, 0 to about 7 wt %, 0 to about 6 wt %, 0 to about 5 wt %, 0 to about 4 wt %, 0 to about 3 wt %, 0 to about 2 wt %, 0 to about 1 wt %, about 1 to about 10 wt %, about 1 to about 9 wt %, about 1 to about 8 wt %, about 1 to about 7 wt %, about 1 to about 6 wt %, about 1 to about 5 wt %, about 1 to about 4 wt %, about 1 to about 3 wt %, about 1 to about 2 wt %, about 2 to about 10 wt %, about 2 to about 9 wt %, about 2 to about 8 wt %, about 2 to about 7 wt %, about 2 to about 6 wt %, about 2 to about 5 wt %, about 2 to about 4 wt %, about 2 to about 3 wt %, about 3 to about 10 wt %, about 3 to about 9 wt %, about 3 to about 8 wt %, about 3 to about 7 wt %, about 3 to about 6 wt %, about 3 to about 5 wt %, about 3 to about 4 wt %, about 4 to about 10 wt %, about 4 to about 9 wt %, about 4 to about 8 wt %, about 4 to about 7 wt %, about 4 to about 6 wt %, about 4 to about 5 wt %, about 5 to about 10 wt %, about 5 to about 9 wt %, about 5 to about 8 wt %, about 5 to about 7 wt %, about 5 to about 6 wt %, about 6 to about 10 wt %, about 6 to about 9 wt %, about 6 to about 8 wt %, about 6 to about 7 wt %, about 7 to about 10 wt %, about 7 to about 9 wt %, about 7 wt % to about 8 wt %, about 8 to about 10 wt %, about 8 to about 9 wt %, about 9 to about 10 wt %, and all ranges and subranges therebetween ZnO. In some embodiments, the glass or glass-ceramic composition can comprise about 0, >0, 1, 2, 3, 4, 5, 6, 7, 8, 9, or 10 wt % ZnO.

In one or more embodiments, the glasses and glass-ceramics herein can comprise from 0 to about 5 wt % TiO₂. In some embodiments, the glass or glass-ceramic composition can comprise from 0 to about 5 wt %, 0 to about 4 wt %, 0 to about 3 wt %, 0 to about 2 wt %, 0 to about 1 wt %, about 1 to about 5 wt %, about 1 to about 4 wt %, about 1 to about 3 wt %, about 1 to about 2 wt %, about 2 to about 5 wt %, about 2 to about 4 wt %, about 2 to about 3 wt %, about 3 to about 5 wt %, about 3 to about 4 wt %, about 4 to about 5 wt %, and all ranges and subranges therebetween TiO₂. In some embodiments, the glass or glass-ceramic composition can comprise about 0, >0, 1, 2, 3, 4, or 5 wt % TiO₂.

In one or more embodiments, the glasses and glass-ceramics herein can comprise from 0 to about 0.4 wt % CeO₂. In some embodiments, the glass or glass-ceramic composition can comprise from 0 to about 0.4 wt %, 0 to about 0.3 wt %, 0 to about 0.2 wt %, 0 to about 0.1 wt %, about 0.1 to about 0.4 wt %, about 1 to about 0.3 wt %, about 1 to about 0.2 wt %, about 0.2 to about 0.4 wt %, about 0.2 to about 0.3 wt %, about 0.3 to about 0.4 wt %, and all ranges and subranges therebetween CeO₂. In some embodiments, the glass or glass-ceramic composition can comprise about 0, >0, 0.1, 0.2, 0.3, or 0.4 wt % CeO₂.

In one or more embodiments, the glasses and glass-ceramics herein can comprise from 0 to about 0.5 wt % SnO₂. In some embodiments, the glass or glass-ceramic composition can comprise from 0 to about 0.5 wt %, 0 to about 0.4 wt %, 0 to about 0.3 wt %, 0 to about 0.2 wt %, 0 to about 0.1 wt %, about 0.05 to about 0.5 wt %, 0.05 to about 0.4 wt %, 0.05 to about 0.3 wt %, 0.05 to about 0.2 wt %, 0.05 to about 0.1 wt %, about 0.1 to about 0.5 wt %, about 0.1 to about 0.4 wt %, about 0.1 to about 0.3 wt %, about 0.1 to about 0.2 wt %, about 0.2 to about 0.5 wt %, about 0.2 to about 0.4 wt %, about 0.2 to about 0.3 wt %, about 0.3 to about 0.5 wt %, about 0.3 to about 0.4 wt %, about 0.4 to about 0.5 wt %, and all ranges and subranges therebetween SnO₂. In some embodiments, the glass or glass-ceramic composition can comprise about 0, >0, 0.05, 0.1, 0.2, 0.3, 0.4, or 0.5 wt % SnO₂.

### Heat Treatments for Crystallization/Ceramming

In one or more embodiments, the processes for making glass-ceramic includes heat treating the precursor glasses at one or more preselected temperatures for one or more preselected times to induce glass homogenization and crystallization (i.e., nucleation and growth) of one or more crystalline phases (e.g., having one or more compositions, amounts, morphologies, sizes or size distributions, etc.). In some embodiments, the heat treatment can include (i) heating precursor glasses at a rate of 1-10° C./min to a glass pre-nucleation temperature: (ii) maintaining the crystallizable glasses at the glass pre-nucleation temperature for a time in a range from about ¼ hr to about 4 hr to produce pre-nucleated crystallizable glasses; (iii) heating the pre-nucleated crystallizable glasses at a rate of 1-10° C./min to nucleation temperature (Tn); (iv) maintaining the crystallizable glasses at the nucleation temperature for a time in the range from between about ¼ hr to about 4 hr to produce nucleated crystallizable glasses; (v) heating the nucleated crystallizable glasses at a rate in the range from about 1° C./min to about 10° C./min to a crystallization temperature (Tc); (vᵢ) maintaining the nucleated crystallizable glasses at the crystallization temperature for a time in the range from about ¼ hr to about 4 hr to produce the glass-ceramic described herein; and (vii) cooling the formed glass-ceramic to room temperature. As used herein, the term crystallization temperature may be used interchangeably with ceram or ceramming temperature. In addition, the terms “ceram” or “ceramming” in these embodiments, may be used to refer to steps (v), (vᵢ) and optionally (vii), collectively. In some embodiments, the glass pre-nucleation temperature can in a range from 500° C. to 600° C. (for example, 500° C., 510° C., 520° C., 530° C., 540° C., 550° C., 560° C., 570° C., 580° C., 590° C., or 600° C.); the nucleation temperature can be in a range from 530° C. to 650° C. (for example, 530° C., 540° C., 550° C., 560° C., 570° C., 580° C., 590° C., 600° C., 610° C., 620° C., 630° C., 640° C., or 650° C.); and/or the crystallization temperature can be in a range from 630° C. to 850° C. (for example, 630° C., 640° C., 650° C., 660° C., 670° C., 680° C., 690° C., 700° C., 710° C., 720° C., 730° C., 740° C., 750° C., 760° C., 770° C., 780° C., 790° C., 800° C., 810° C., 820° C., 830° C., 840° C., or 850° C.). In some embodiments, the crystallization temperature depends on whether a transparent or trasnslucent/opaque glass-ceramic is desired. In some embodiments, a crystallization temperature of about 750° C. or below will result in a transparent glass-ceramic and a crystallization temperature above about 750° C. will result in a translucent/opaque glass-ceramic. In some embodiments, the glass can be heated to a pre-nucleation temperature of 540° C., maintained at the pre-nucleation temperature for 4 hours, heated to a nucleation temperature of 600° C., maintained at the nucleation temperature for 4 hours, heated to the crystallization temperature of 730° C., and maintained at the nucleation temperature for 4 hours.

In other embodiments, the heat treatment does not include maintaining the crystallizable glasses at a glass pre-nucleation temperature. Thus the heat treatment may include (i) heating precursor glasses at a rate of 1-10° C./min to a nucleation temperature (Tn); (ii) maintaining the crystallizable glasses at the nucleation temperature for a time in the range from between about ¼ hr to about 4 hr to produce nucleated crystallizable glasses; (iii) heating the nucleated crystallizable glasses at a rate in the range from about 1° C./min to about 10° C./min to a crystallization temperature (Tc); (iv) maintaining the nucleated crystallizable glasses at the crystallization temperature for a time in the range from about ¼ hr to about 4 hr to produce the glass-ceramic described herein; and (v) cooling the formed glass-ceramic to room temperature. The terms “ceram” or “ceramming”, in the preceding embodiments, may be used to refer to steps (iii), (iv) and optionally (v), collectively. In some embodiments, the nucleation temperature can in a range from can be in a range from 500° C. to 650° C. (for example, 500° C., 510° C., 520° C., 530° C., 540° C., 550° C., 560° C., 570° C., 580° C., 590° C., 600° C., 610° C., 620° C., 630° C., 640° C., or 650° C.); and/or the crystallization temperature can be in a range from 600° C. to 850° C. (for example, 600° C., 610° C., 620° C., 630° C., 640° C., 650° C., 660° C., 670° C., 680° C., 690° C., 700° C., 710° C., 720° C., 730° C., 740° C., 750° C., 760° C., 770° C., 780° C., 790° C., 800° C., 810° C., 820° C., 830° C., 840° C., or 850° C.740° C., 750° C., 760° C., 770° C., 780° C., 790° C., 800° C., 810° C., 820° C., 830° C., 840° C., or 850° C.). In some embodiments, the crystallization temperature depends on whether a transparent or translucent/opaque glass-ceramic is desired. In some embodiments, a crystallization temperature of about 750° C. or below will result in a transparent glass-ceramic and a crystallization temperature above about 750° C. will result in a translucent/opaque glass-ceramic. In some embodiments, the glass can be heated to a nucleation temperature of 560° C., maintained at the nucleation temperature for 4 hours, heated to the crystallization temperature of 720° C., and maintained at the crystallization temperature for 1 hour.

Temperature-temporal profile of heat treatment steps of heating to the crystallization temperature and maintaining the temperature at the crystallization temperature in addition to precursor glass compositions, are judiciously prescribed so as to produce one or more of the following desired attributes: crystalline phase(s) of the glass-ceramic, proportions of one or more major crystalline phases and/or one or more minor crystalline phases and residual glass, crystal phase assemblages of one or more predominate crystalline phases and/or one or more minor crystalline phases and residual glass, and grain sizes or grain size distributions among one or more major crystalline phases and/or one or more minor crystalline phases, which in turn may influence the final integrity, quality, color, and/or opacity, of resultant formed glass-ceramic.

Upon performing the above heat treatments to the precursor glass, the resultant glass-ceramic has one or more crystalline phases and a residual glass phase. In some embodiments, the glass-ceramic contains the following exemplary crystalline phases: lithium disilicate, petalite, β-spodumene solid solution, β-quartz solid solution, and any combinations thereof. In some embodiments there may be a mixture of lithium disilicate, petalite, and β-quartz solid solution crystalline phases. In other embodiments, there may be a mixture of lithium disilicate and petalite crystalline phases. In yet other embodiments, there may be a mixture of lithium disilicate and β-spodumene solid solution crystalline phases. In still other embodiments, there may be a mixture of lithium disilicate, β-spodumene solid solution, and β-quartz solid solution crystalline phases. In some embodiments, lithium disilicate is the crystalline phase with the highest weight percentage. In some embodiments petalite is the crystalline phase with the highest weight percentage. In some embodiments, β-spodumene ss is the crystalline phase with the highest weight percentage. In some embodiments, β-quartz ss is the crystalline phase with the highest weight percentage In some embodiments, the glass-ceramic has a residual glass content of about 5 to about 30 wt %, about 5 to about 25 wt %, about 5 to about 20 wt %, about 5 to about 15 wt % about 5 to about 10 wt %, about 10 to about 30 wt %, about 10 to about 25 wt %, about 10 to about 20 wt %, about 10 to about 15 wt %, about 15 to about 30 wt %, about 15 to about 25 wt %, about 15 to about 20 wt %, about 20 to about 30 wt % about 20 to about 25 wt %, about 25 to about 30 wt %, and all ranges and subranges therebetween. In some embodiments the residual glass content can be 5, 6, 7, 8, 9, 10, 11, 12, 13, 14, 15, 16, 17, 18, 19, 20, 21, 22, 23, 24, 25, 26, 27, 28, 29, or 30 wt %. In some embodiments, the inner region may have a weight percentage of crystals in a range from greater than 20 wt % to 100 wt %, greater than 20 wt % to 90 wt %, greater than 20 wt % to 80 wt %, greater than 20 wt % to 70 wt %, 30 wt % to 100 wt %, 30 wt % to 90 wt %, 30 wt % to 80 wt %, 30 wt % to 70 wt %, 40 wt % to 100 wt %, 40 wt % to 90 wt %, 40 wt % to 80 wt %, 40 wt % to 70 wt %, 50 wt % to 100 wt %, 50 wt % to 90 wt %, 50 wt % to 80 wt %, 50 wt % to 70 wt %, and all ranges and subranges therebetween. In some embodiments, the inner region may have a weight percentage of crystals greater than 20 wt %, 25 wt %, 30 wt %, 35 wt %, 40 wt %, 45 wt %, 50 wt %, 55 wt %, 60 wt %, 65 wt %, 70 wt %, 75 wt %, 80 wt %, 85 wt %, or 90 wt %.

### Ion Exchange

In some embodiments, the glass-ceramic article is capable of being chemically strengthened using one or more ion exchange techniques. In these embodiments, ion exchange can occur by subjecting one or more surfaces of such glass-ceramic article to one or more ion exchange mediums (for example molten salt baths), having a specific composition and temperature, for a specified time period to impart to the one or more surfaces with compressive stress layer(s). In some embodiments, the ion exchange medium is a molten bath containing an ion (for example an alkali metal ion) that is larger than an ion (for example an alkali metal ion) present in the glass-ceramic article wherein the larger ion from the molten bath is exchanged with the smaller ion in the glass-ceramic article to impart a compressive stress in the glass-ceramic article, and thereby increases the strength of the glass-ceramic article. As noted above, in some embodiments, when glass-ceramic articles are subjected to the ion exchange conditions described below the residual glass phase is ion-exchanged and one or more of the crystalline phases can be “decrystallized” to form a surface region or layer that has a lower weight percentage of crystals than an inner region of the glass-ceramic article. In this decrystallization process one or more of the crystalline phases can be broken down by the ion exchange process.

In some embodiments, a one step ion exchange process can be used and in other embodiments, a multi step ion exchange process can be used. In some embodiments, for both one step and multi step ion exchange processes the ion exchange mediums (for example, molten baths) can include 100 wt % of a sodium-containing salt (for example, NaNO₃) or can include a mixed salt bath, for example a combination of a sodium-containing salt (for example, NaNO₃) and a potassium-containing salt (for example KNO₃). In some embodiments, when the molten salt bath contains a sodium-containing salt (for example, NaNO₃) in a range from 3 wt % to 100 wt %, 3 wt % to 95 wt %, 3 wt % to 90 wt %, 3 wt % to 85 wt %, 3 wt % to 80 wt %, 3 wt % to 75 wt %, 5 wt % to 100 wt %, 5 wt % to 95 wt %, 5 wt % to 90 wt %, 5 wt % to 85 wt %, 5 wt % to 80 wt %, 5 wt % to 75 wt %, 10 wt % to 100 wt %, 10 wt % to 95 wt %, 10 wt % to 90 wt %, 10 wt % to 85 wt %, 10 wt % to 80 wt %, 10 wt % to 75 wt %, 20 wt % to 100 wt %, 20 wt % to 95 wt %, 20 wt % to 90 wt %, 20 wt % to 85 wt %, 20 wt % to 80 wt %, 20 wt % to 75 wt %, 30 wt % to 100 wt %, 30 wt % to 95 wt %, 30 wt % to 90 wt %, 30 wt % to 85 wt %, 30 wt % to 80 wt %, 30 wt % to 75 wt %, and all ranges and subranges therebetween. In some embodiments, molten salt bath contains a sodium-containing salt (for example, NaNO₃) greater than or equal to 3 wt %, 5 wt %, 10 wt %, 15 wt %, 20 wt %, 25 wt %, 30 wt %, 35 wt %, 40 wt %, 45 wt %, 50 wt %, 55 wt %, 60 wt %, 65 wt %, 70 wt %, 75 wt %, 80 wt %, 85 wt %, 90 wt %, or 95 wt %. In some embodiments, the molten salt baths may also include up to 1% by weight of NaNO₂ (for example 0.25 wt %, 0.5 wt %, 0.75 wt %, or 1 wt %) because it interacts with alkaline earth metals to reduce impurities in the molten salt bath.

In some embodiments, for a one step ion exchange process the ion exchange occurs in a fresh bath, wherein a bath is considered fresh if it contains less than 0.03 wt %, less than 0.02 wt %, less than 0.01 wt %, less than 0.009 wt %, less than 0.008 wt %, less than 0.007 wt %, less than 0.006 wt %, less than 0.005 wt %, or less than 0.0004 wt % total of lithium-containing poisoning salts including, but not limited to, LiNO₃ and LiNO₂. Having a fresh molten bath facilitates a quicker time for formation and ultimate depth of vitreous outer regions as shown in the examples below.

In some embodiments, for a multi step ion exchange process, for example a two step ion exchange process, can include a first ion exchange step wherein the ion exchange medium (for example, a molten salt bath) is poisoned with lithium-containing salt(s) and the second ion exchange step occurs in an ion exchange medium (for example, a molten salt bath) having a lower total content of lithium-containing poisoning salts. The molten salt bath in the first ion exchange step is intentionally poisoned to a level that prevents the formation of the vitreous outer region during the first step. In some embodiments, the molten salt bath in the first ion exchange step contains a total of lithium-containing salt(s) (for example, LiNO₃ and/or LiNO₂) in a range from 0.03 wt % to 0.5 wt %, 0.03 wt % to 0.4 wt %, 0.03 wt % to 0.3 wt %, 0.03 wt % to 0.2 wt %, 0.03 wt % to 0.1 wt %, 0.05 wt % to 0.5 wt %, 0.05 wt % to 0.4 wt %, 0.05 wt % to 0.3 wt %, 0.05 wt % to 0.2 wt %, 0.05 wt % to 0.1 wt %, 0.07 wt % to 0.5 wt %, 0.07 wt % to 0.4 wt %, 0.07 wt % to 0.3 wt %, 0.07 wt % to 0.2 wt %, 0.07 wt % to 0.1 wt %, 0.1 wt % to 0.5 wt %, 0.1 wt % to 0.4 wt %, 0.1 wt % to 0.3 wt %, 0.1 wt % to 0.2 wt %, 0.2 wt % to 0.5 wt %, 0.2 wt % to 0.4 wt %, and all ranges and subranges therebetween. In the first ion exchange step a deep compressive stress layer is formed and then during the second ion exchange step the vitreous outer region(s) are formed. In some embodiments, the ion exchange medium (for example, a molten salt bath) in the first ion exchange step contains a total of lithium-containing salt(s) (for example, LiNO₃ and/or LiNO₂) that is greater than the total of lithium-containing salt(s) in the second ion exchange medium (for example, a molten salt bath) in the second ion exchange step by at least 0.01 wt %, 0.02 wt %, 0.03 wt %, 0.04 wt %, or 0.05 wt %. In some embodiments, the level of poisoning that prevents the formation of a vitreous outer region is higher for the second step of a two step ion exchange than the level of poisoning that prevents the formation of a vitreous outer region in the same bath but used for a single step ion exchange, for example the upper limit for the permissible level of poisoning in the second step of the two step ion exchange process can be at least 25%, at least 30%, at least 35%, at least 40%, at least 45% or at least 50% greater than the permissible level of poisoning for the same bath but used for a single step ion exchange. In some embodiments, this two-step process results in a thicker vitreous outer region than a one step ion exchange process. These trends are exemplified in the examples below.

In some embodiments, the first ion exchange medium is maintained at higher temperature than the second ion exchange medium, and/or the glass-ceramic article is contacted with the first ion exchange medium for a longer time than it is contacted with the second ion exchange medium. In some embodiments, the multi-step ion exchange can include a third ion exchange.

### End Products

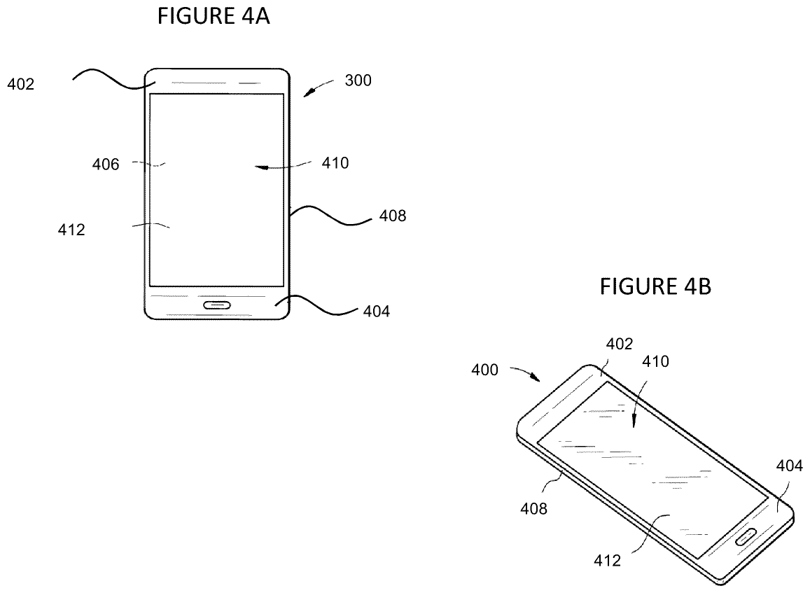

The strengthened glass-ceramic articles disclosed herein may be incorporated into another article such as an article with a display (or display articles) (e.g., consumer electronics, including mobile phones, tablets, computers, navigation systems, wearable devices (e.g., watches) and the like), architectural articles, transportation articles (e.g., automotive, trains, aircraft, sea craft, etc. for example for use an interior display cover, a window, or windshield), appliance articles, or any article that requires some transparency, scratch-resistance, abrasion resistance or a combination thereof. An exemplary article incorporating any of the strengthened glass-ceramic articles disclosed herein is shown in FIGS. 4A and 4B. Specifically, FIGS. 4A and 4B show a consumer electronic device 400 including a housing 402 having front 404, back 406, and side surfaces 408; electrical components (not shown) that are at least partially inside or entirely within the housing and including at least a controller, a memory, and a display 410 at or adjacent to the front surface of the housing; and a cover substrate 412 at or over the front surface of the housing such that it is over the display. In some embodiments, at least one of the cover substrate 412 or a portion of housing 402 may include any of the glass-ceramic strengthened articles disclosed herein.

### EXAMPLES

Various embodiments will be further clarified by the following examples.

### Example 1

Precursor glass samples having a thickness of 800 microns were formed having a composition in wt % on an oxide basis of: 73.47% SiO₂, 7.51% Al₂O₃, 2.14% P₂O₅, 11.10% Li₂O, 1.63% Na₂O, 3.55% ZrO₂, and 0.22 SnO₂. The precursor glass samples were then subjected to a ceramming schedule having a glass homogenization hold at 540° C. for 4 hours, followed by a nucleation hold at 600° C. for 4 hours, and followed by a crystallization hold at 730° C. for 4 hours to form a glass-ceramic. The glass-ceramic had lithium disilicate and petalite crystalline phases and a residual glass phase.

Samples were then ion exchanged under the following conditions listed in Table 2 below.

TABLE 2

| Sample | IOX conditions |
|---|---|
| 1 | 470° C. for 4 hours in a molten salt bath having 40 wt % |
| | NaNO₃ and 60 wt % KNO₃ with a 0.5% NaNO₂ additive by |
| | weight. |
| 2 | 470° C. for 7 hours in a molten salt bath having 40 wt % |
| | NaNO₃ and 60 wt % KNO₃ with a 0.5% NaNO₂ additive by |
| | weight. |
| 3 | 470° C. for 16 hours in a molten salt bath having 40 wt % |
| | NaNO₃ and 60 wt % KNO₃ with a 0.5% NaNO₂ additive by |
| | weight. |

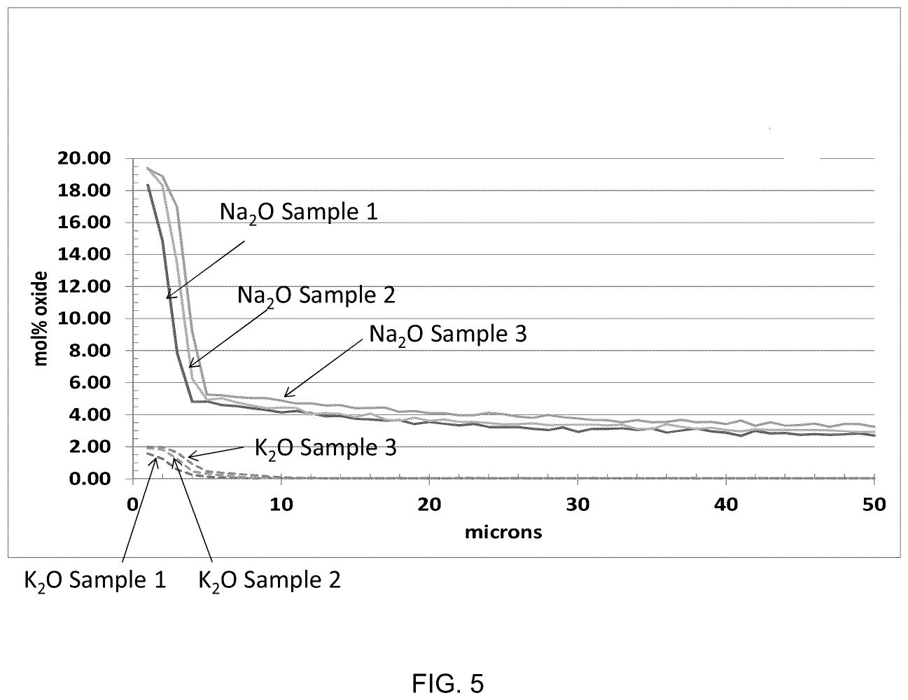

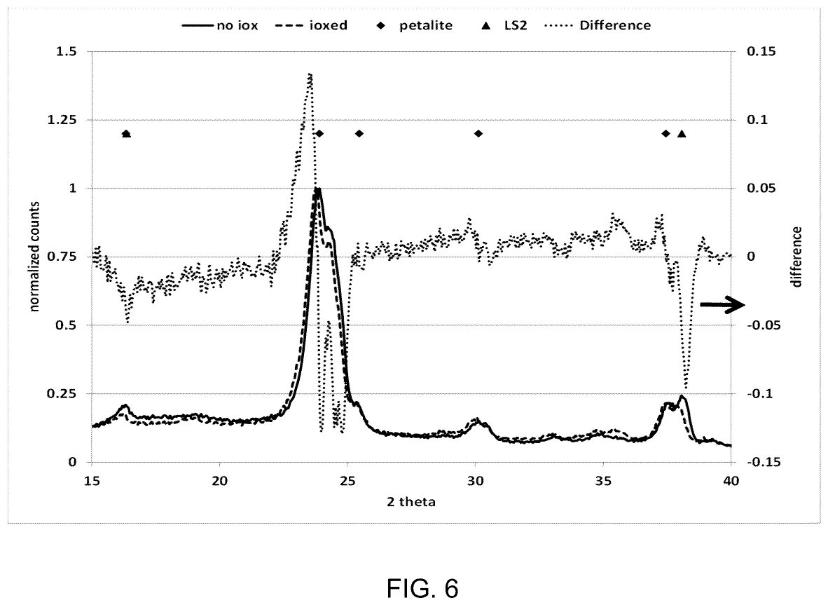

FIG. 5 is a plot of the Na₂O and K₂O concentration profile in mol % as measured by microprobe. The Na₂O concentration at the surface for all three samples is in the range of 18 to 20 mol %. This is evidence that some portion of the crystals in the glass-ceramic undergo ion exchange. X-ray diffraction traces were taken of a sample before ion exchange and after ion exchange under the conditions of sample 1 as shown in FIG. 6. As can be seen, the X-ray diffraction trace of the ion exchanged glass-ceramic showed a decrease in the crystalline content (lithium disilicate and petalite phases). Without being bound by theory, it is believed that the crystals in the glass-ceramic undergo ion exchange so that when lithium is taken out of the crystals the sodium counterpart of the crystal is destabilized by the incoming ions resulting in a vitreous region of approximately 5 microns in thickness.

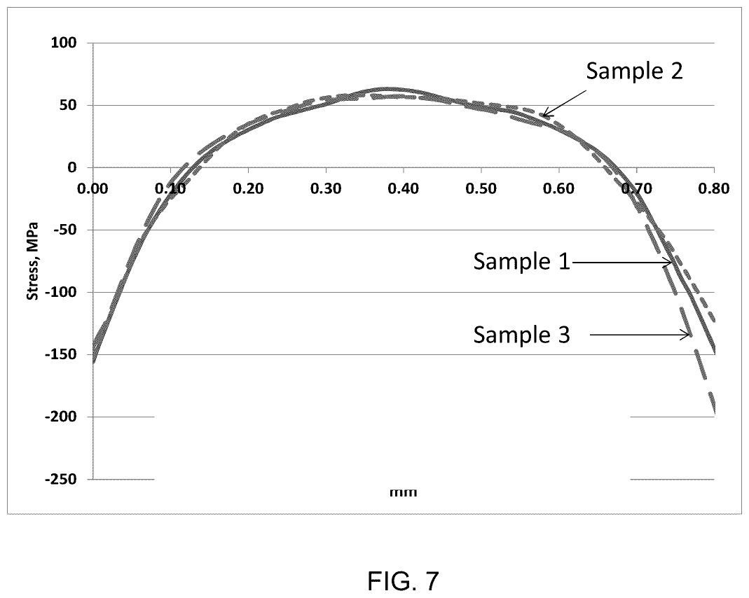

FIG. 7 is a stress profile of Samples 1-3 after ion exchange measured by the combination of techniques described above and is shown in an opposite convention from FIG. 2 in that the compressive stress is shown as being negative and the tensile stress is shown as being positive. The stress profiles are substantially parabolic in shape. The maximum tensile stress is over 50 MPa.

### Example 2

Non-ion exchanged glass-ceramic samples having a thickness of 800 microns were formed according to the procedure of Example 1. Samples were ion exchanged according to the conditions in Table 3 below and the reduced modulus, hardness and penetration depth were measured using the nanoindentation technique describe above. The depth of a vitreous region that is formed during ion exchange was also measured using GDEOS (glow discharge optical emission spectroscopy) based on the change in alkali metal ion concentration. It is noted that GDEOS is an alternative technique for measuring the depth of the vitreous region from the SEM measurement technique described above. The average maximum scratch width was also measured according to the Scratch Test described above based on an average of 15 measurements for each sample at a load of 1 N, 3 N, and 5 N.

TABLE 3

| | | | | Depth of | Avg max | Avg max | Avg max |
|---|---|---|---|---|---|---|---|
| | Reduced | | | Vitreous | width | width | width |
| IOX | Modulus | Hardness | Depth | region | (μm) at | (μm) at | (μm) at |
| conditions | (GPa) | (GPa) | (nm) | (μm) | 1N load | 3N load | 5N load |
| No IOX | 101 | 8.8 | 137.2 | 0 | 146.4 | 310.4 | 378.8 |
| 470° C.; 4 hrs; | 84 | 7 | 155.8 | 2.8 | 66.2 | 105.7 | 111.1 |
| molten salt | | | | | (1^{st} set) | (1^{st} set) | (1^{st} set) |
| bath 95 | | | | | 21.9 | 100.3 | 99.7 |
| wt % NaNO₃/5 | | | | | (2^{nd} set) | (2^{nd} set) | (2^{nd} set) |
| wt % KNO₃ | | | | | | | |
| 1^{st} IOX: | 97.8 | 8 | 144.3 | 0.44 | 118.0 | 235.9 | 220.9 |
| 460° C.; 8 hrs; | | | | | | | |
| molten salt | | | | | | | |
| bath 100% | | | | | | | |
| KNO₃ | | | | | | | |
| 2^{nd} IOX: | | | | | | | |
| 430° C.; 6 hrs; | | | | | | | |
| molten salt | | | | | | | |
| bath 90 wt % | | | | | | | |
| KNO₃/10 wt % | | | | | | | |
| NaNO₃ | | | | | | | |

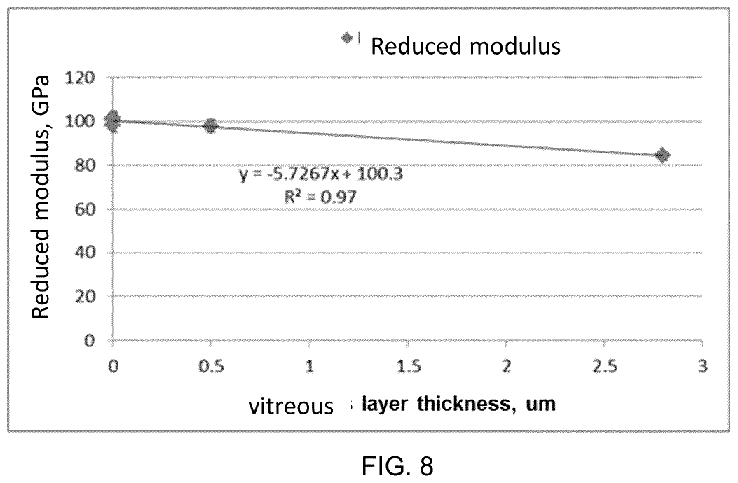

As can be seen from the data above a vitreous region was formed during both ion exchanges, but that the thickness for the vitreous region for the sample ion exchanged in the 95 wt % NaNO₃ salt bath was greater. The two step ion exchange was used as a control to minimize the formation of a vitreous region to show how a thicker vitreous region lead to a lower reduced modulus, a lower hardness, and lower average maximum scratch width. For example, the plot of FIG. 8 where the reduced modulus (GPa) is on the y axis and the vitreous region thickness (μm) on the x axis shows that the greater the thickness of the vitreous region, the lower the reduced modulus. A line was extrapolated between the data points having an equation of 7=−5.7267x+100.3 with an R² value of 0.97.

The data shown in Table 3 also shows that samples with the best scratch performance—the lowest average maximum scratch width-occurred for the samples that were ion exchanged in the 95 wt % NaNO₃ salt bath and had the larger vitreous region thickness. Two sets of measurements were made on the sample with the Scratch Test for the 95 wt % NaNO₃ salt bath ion exchange. The measurements at loads of 3 N and 5 N were similar, however the measurements at a load of IN varied. It is believed that measurements at a load of IN varied because at a load of IN there was a greater likelihood of lateral cracking when the scratches were made, which increased the width measurements.

### Example 3

Non-ion exchanged glass-ceramic samples having a thickness of 800 microns were formed according to the procedure of Example 1. A first sample was ion exchanged in a molten salt bath having 95 wt % NaNO₃ and 5 wt % KNO₃ with a 0.5% NaNO₂ additive by weight at 470° C. for 4.5 hours. The bath was fresh in that it contained less than about 0.01 wt % of LiNO₃ and LiNO₂. The first sample had a region at the surface depleted of a crystalline phase (had more amorphous phase in this region than before ion exchange) of about 5 microns in thickness. The average compressive stress of the region was about 200 MPa. The region had a reduced modulus of about 84 GPa compared to the reduced modulus of about 100 GPa of the glass-ceramic before ion exchange. There was a gradient in the Na₂O concentration from the surface to a depth exceeding 30% of the thickness. The depth of the compression was between 13 and 20% of the thickness as measured by SCALP and the maximum central tension was about 65 MPa.

A second sample was ion exchanged in a molten salt bath having 95 wt % NaNO₃ and 5 wt % KNO₃ with a 0.5% NaNO₂ additive by weight at 470° C. for 4 hours and was poisoned in that it contained greater than about 0.03% by weight of LiNO₃ and LiNO₂. The lithium poisoning of the bath is believed to have prevented the formation of a vitrified layer. The second sample has a similar or slightly lower central tension compared to the first sample and a maximum width of the scratch made by performing the scratch test described above at loads of IN, 3 N, and 5 N were approximately twice as wide for the second sample (approximately 200 microns at 5 N load) as the first sample (approximately 100 microns at 5 N load)

### Example 4

Thirty samples of glass-ceramic were prepared as outlined in Example 1 having dimensions of 50 mm×50 mm×0.8 mm. The thirty samples were subjected to a first ion exchange in a molten salt bath of NaNO₃ with a 0.5% NaNO₂ additive by weight at 460° C. for 4 hours. The molten salt bath was intentionally poisoned in that it contained between 0.04 to 0.05 wt % LiNO₃. It is believed that the poisoning of the bath prevented a vitrified region from forming as a result of the first ion exchange. The samples were then sequentially subjected to a second ion exchange in sets of 6 starting with a fresh molten salt bath of 2.6 kg NaNO₃ with a 0.5% NaNO₂ additive by weight under the following conditions listed below in Table 4.

TABLE 4

| Set | Conditions |
|---|---|
| 1 | 450° C.; 1 hr 20 min with samples spaced 10 mm apart |
| 2 | 450° C.; 1 hr 20 min with samples spaced 10 mm apart |
| 3 | 450° C.; 1 hr 20 min with samples spaced 10 mm apart |
| 4 | 450° C.; 2 hrs with samples spaced 10 mm apart |
| 5 | 450° C.; 3 hrs with samples spaced 10 mm apart |
| 6 | 450° C.; 5 hrs with samples spaced 10 mm apart |

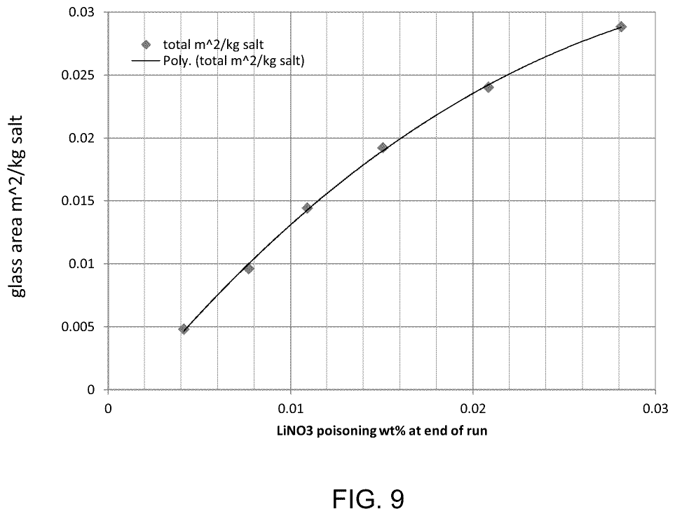

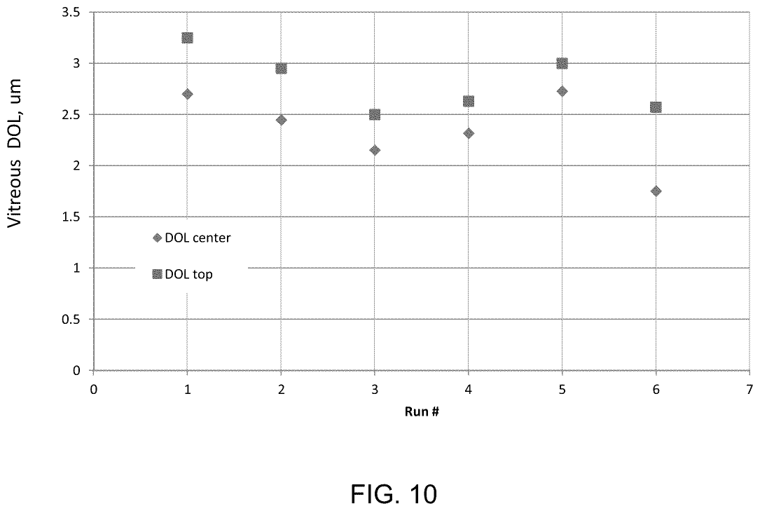

FIG. 9 shows a plot of the total area of the samples with the vitrified region per kg of salt in the bath vs the lithium poisoning (wt % LiNO₃) that had occurred at the end of each run. FIG. 9 shows that after the sixth run the samples of set 6 had approximately 6 times more vitrified region than the samples of set 1 after the first run. FIG. 10 shows the thickness (DOL) of each of the vitreous region for each set of samples. The samples were dipped in the ion exchange bath in a vertical orientation and DOL of the vitreous regions were measured by GDEOS at a spot on the surface that was at the top of the ion exchange bath (referred to as “DOL top” in FIG. 10) and at spot on the center of the surface (referred to as “DOL center” in FIG. 10). The DOL top measurements were greater than the DOL center measurements and is indicative that there is a decreasing gradient in the thickness of the vitreous region across the surface of the glass-ceramic samples from the edge that was at the top of the ion exchange bath to the edge that was at the bottom of the ion exchange bath. It is believed that this phenomena could be prevented by agitating the ion exchange bath.

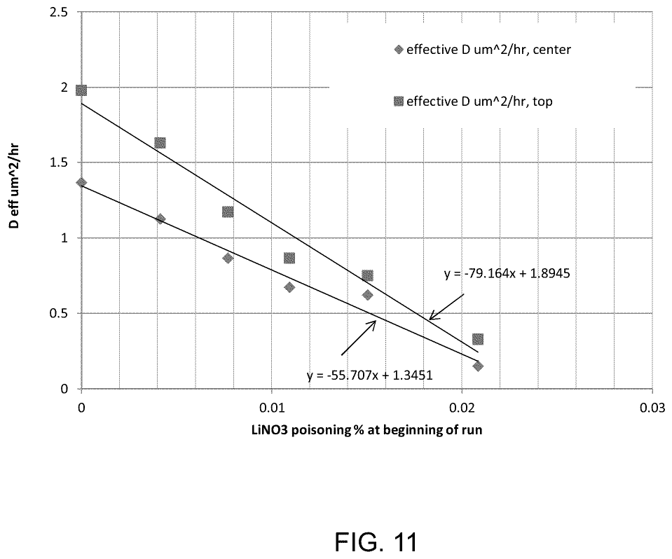

The effective diffusion coefficient (Deff) was measured for a sample from each set and the Deff was plotted vs the wt % of LiNO₃ at the start of each run as shown in FIG. 11. The Deff is related to the DOL of the vitreous region by the following relationship: DOL=2*V (Deff *t), where t is time. As can be seen the Deff decreases with an increase in lithium poisoning and is still above 0 when the poisoning exceeds 0.02 wt % LiNO₃. FIG. 11 reports Deff top and Deff center which are based on calculating the Deff from the DOL top and DOL center. This level of poisoning exceeds the limiting poisoning for formation of the vitrified region with a single IOX step by at least 50%.

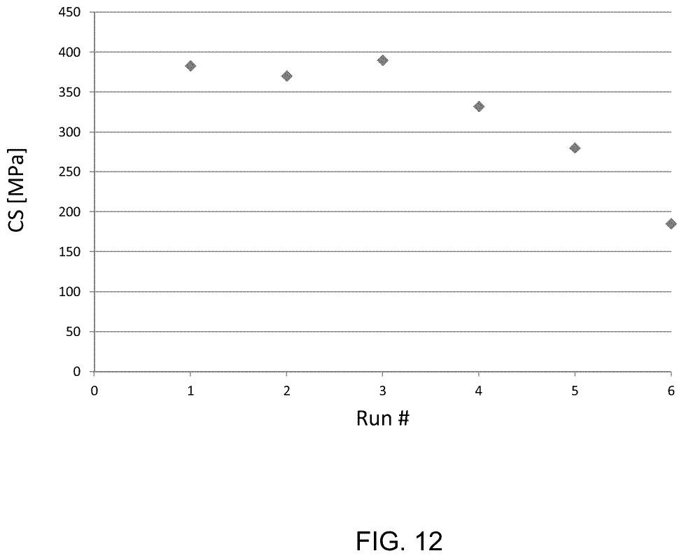

FIG. 12 shows the average compressive stress of the vitrified region for each set of samples and shows that the average compressive stress of the vitrified region started to decrease after run 3.

It will be apparent to those skilled in the art that various modifications and variations can be made without departing from the spirit or scope of the invention. For example, the various features may be combined according to the following Embodiments.

Embodiment 1. A glass-ceramic article comprising:
a first surface;
a second surface opposing the first surface;
a first region extending from the first surface to a first depth d1;
a second region extending from a depth greater than or equal to d1 to a second depth d2, wherein the second region comprises a crystalline phase and a glass phase; and
a compressive stress layer extending from the first surface to a depth of compression (DOC),
wherein an area percentage % of crystals in the first region is less than an area percentage % of crystals in the second region,
wherein the DOC is greater than or equal to 0.05 mm, and
wherein an average compressive stress in the first region is greater than or equal to 50 MPa.

Embodiment 2. The glass-ceramic article of Embodiment 1, wherein the DOC is greater than or equal to 0.1 mm.

Embodiment 3. A glass-ceramic article comprising:
a first surface;
a second surface opposing the first surface;
a first region extending from the first surface to a first depth d1;
a second region extending from a depth greater than or equal to d1 to a second depth d2, wherein the second region comprises a crystalline phase and a glass phase; and
a compressive stress layer extending from the first surface to a depth of compression (DOC),
wherein an area percentage of crystals in the first region is less than an area percentage of crystals in the second region, and
wherein the DOC is greater than d1.

Embodiment 4. The glass-ceramic article of Embodiment 3, wherein the DOC is greater than or equal to 0.05*t, wherein t is a thickness of the glass-ceramic article.

Embodiment 5. The glass-ceramic article of Embodiment 3, wherein the DOC is greater than or equal to 0.1*t, wherein t is a thickness of the glass-ceramic article.

Embodiment 6. The glass-ceramic article of any preceding Embodiment, wherein a reduced modulus of the first region is less than the reduced modulus of the second region.

Embodiment 7. The glass-ceramic article of any preceding Embodiment, wherein a hardness of the first region is less than the hardness of the second region.

Embodiment 8. The glass-ceramic article of any preceding Embodiment, wherein the first surface has an average maximum scratch width of less than 155 microns when subjected to the Scratch Test at load of 5 N based on an average of 15 measurements.

Embodiment 9. A glass-ceramic article comprising:
a first surface;
a second surface opposing the first surface;
a first region extending from the first surface to a first depth d1; and
a second region extending from a depth greater than or equal to d1 to a second depth, wherein the second region comprises a crystalline phase and a glass phase,
wherein an area percentage of crystals in the first region is less than an area percentage of crystals in the second region, and
wherein a reduced modulus of the first region is less than the reduced modulus of the second region.

Embodiment 10. The glass-ceramic article of Embodiment 9, wherein the reduced modulus of the first region is at least 5% less than the reduced modulus of the second region.

Embodiment 11. A glass-ceramic article comprising:
a first surface;
a second surface opposing the first surface;
a first region extending from the first surface to a first depth d1; and
a second region extending from a depth greater than or equal to d1 to a second depth d2, wherein the second region comprises a crystalline phase and a glass phase,
wherein an area percentage of crystals in the first region is less than an area percentage of crystals in the second region, and
wherein a hardness of the first region is less than the hardness of the second region.

Embodiment 12. The glass-ceramic article of Embodiment 11, wherein the hardness of the first region is at least 5% less than the hardness of the second region.

Embodiment 13. The glass-ceramic article of Embodiment 11 or 12, wherein a reduced modulus of the first region is less than the reduced modulus of the second region.

Embodiment 14. A glass-ceramic article comprising:
a first surface having an average maximum scratch width of less than 155 microns when subjected to the Scratch Test at load of 5 N based on an average of 15 measurements;
a second surface opposing the first surface;
a first region extending from the first surface to a first depth d1; and
a second region extending from a depth greater than or equal to d1 to a second depth d2, wherein the second region comprises a crystalline phase and a glass phase and wherein an area percentage of crystals in the first region is less than an area percentage of crystals in the second region.

Embodiment 15. The glass-ceramic article of Embodiment 14, wherein the first surface has an average maximum scratch width of less than 150 microns when subjected to the Scratch Test at load of 3 N based on an average of 15 measurements.

Embodiment 16. The glass-ceramic article of Embodiment 14 or 15, wherein the first surface has an average maximum scratch width of less than 100 microns when subjected to the Scratch Test at load of 1 N based on an average of 15 measurements.

Embodiment 17. A glass-ceramic article comprising:
a first surface having an average maximum scratch width of less than 100 microns when subjected to the Scratch Test at load of 1 N based on an average of 15 measurements;
a second surface opposing the first surface;
a first region extending from the first surface to a first depth d1; and
a second region extending from a depth greater than or equal to d1 to a second depth d2, wherein the second region comprises a crystalline phase and a glass phase and wherein an area percentage of crystals in the first region is less than an area percentage of crystals in the second region.

Embodiment 18. The glass-ceramic article of Embodiment 14, wherein the first surface has an average maximum scratch width of less than 150 microns when subjected to the Scratch Test at load of 3 N based on an average of 15 measurements.

Embodiment 19. The glass-ceramic article of any one of Embodiments 14-18, wherein a reduced modulus of the first region is less than the reduced modulus of the second region.

Embodiment 20. The glass-ceramic article of any one of Embodiments 14-19, wherein a hardness of the first region is less than the hardness of the second region.

Embodiment 21. The glass-ceramic article of any preceding Embodiment, wherein the glass-ceramic article is lithium-containing.

Embodiment 22. The glass-ceramic article of Embodiment 21, wherein the crystalline phase comprises lithium disilicate.

Embodiment 23. The glass-ceramic article of Embodiment 21 or 22, wherein the crystalline phase comprises one or more of petalite, β-spodumene solid solution, or β-quartz solid solution.

Embodiment 24. The glass-ceramic article of any preceding Embodiment, where in depth d1 is at least 100 nm.

Embodiment 25. The glass-ceramic article of any preceding Embodiment, wherein d1 is in a range from 100 nm to 25 μm.

Embodiment 26. The glass-ceramic article of any preceding Embodiment, wherein d1 is in a range from 1 μm to 4 μm.

Embodiment 27. The glass-ceramic article of any preceding Embodiment, wherein the first region has a lower refractive index than the second region.

Embodiment 28. The glass-ceramic article of any preceding Embodiment, wherein a depth of compression in a range from 0.05*t to 0.3*t, wherein t is the thickness of the glass-ceramic article.

Embodiment 29. The glass-ceramic article of any preceding Embodiment, wherein an average compressive stress in the first region of the glass-ceramic article is in a range from 50 MPa to 1500 MPa.

Embodiment 30. The glass-ceramic article of any preceding Embodiment, wherein the inner region has a compressive stress at least 5 microns into the inner region of at least 10 MPa.

Embodiment 31. The glass-ceramic article of any preceding Embodiment, wherein the inner region has a compressive stress at least 5 microns into the inner region of at least 30 MPa.

Embodiment 32. The glass-ceramic article of any preceding Embodiment, wherein a maximum central tension in units of MPa is in a range from 10 to 170/Vt, wherein t is the thickness of the glass-ceramic article in millimeters.

Embodiment 33. The glass-ceramic article of any preceding Embodiment, wherein a maximum central tension is in a range from 40 MPa to 150 MPa.

Embodiment 34. The glass-ceramic article of any preceding Embodiment, wherein the glass-ceramic article is transparent and has a transmittance of at least 85% for light in a wavelength range from 450 nm to 600 nm at a thickness of 1 mm.

Embodiment 35. The glass-ceramic article of any preceding Embodiment, further comprising a third region from the second surface to a third depth d1′ measured from the second surface, wherein an area percentage of crystals in the third region is less than an area percentage of crystals in the second region.

Embodiment 36. The glass-ceramic article of Embodiment 35, wherein the first depth d1 is greater than the third depth d1′

Embodiment 37. The glass-ceramic article of Embodiment 36, wherein the first depth d1 is greater than third depth d1′ by at least 5%.

Embodiment 38. The glass-ceramic article of any one of Embodiments 35-37, wherein a compressive stress at the first surface is greater than the compressive stress at the second surface.

Embodiment 39. The glass-ceramic article of any one of Embodiments 35-38, wherein a reduced modulus of the third region is less than the reduced modulus of the second region.

Embodiment 40. The glass-ceramic article of any one of Embodiments 35-39, wherein a hardness of the third region is less than the hardness of the second region.

Embodiment 41. The glass-ceramic article of any one of Embodiments 35-40, wherein the second surface has an average maximum scratch width of less than 155 microns when subjected to the Scratch Test at load of 5 N based on an average of 15 measurements.

Embodiment 42. The glass-ceramic article of any one of Embodiments 35-41, wherein the compressive stress at the first surface is greater than the compressive stress at the second surface by at least 5%.

Embodiment 43. The glass-ceramic article of any preceding Embodiment, wherein a thickness t of the glass-ceramic article is 4 mm or less.

Embodiment 44. The glass-ceramic article of Embodiment 43, wherein the thickness of the glass-ceramic article is 1 mm or less.

Embodiment 45. The glass-ceramic article of any preceding Embodiment, wherein the area percentage of crystals in the first region is 0

Embodiment 46. The glass-ceramic article of any preceding Embodiment, further comprising a transition region between the first region and the inner region.

Embodiment 47. The glass-ceramic article of any one of Embodiments 1-46, wherein the glass-ceramic article is not a laminate.

Embodiment 48. The glass-ceramic article of any one of Embodiments 1-45, wherein the glass-ceramic article is a laminate, the second region is a glass-ceramic and the first region is a glass.

Embodiment 49. A consumer electronic product, comprising
a housing comprising a front surface, a back surface and side surfaces;
electrical components at least partially within the housing, the electrical components comprising at least a controller, a memory, and a display, the display at or adjacent the front surface of the housing; and
a cover substrate disposed over the display,
wherein at least one of a portion of the housing or the cover substrate comprises the glass-ceramic article of any of the preceding Embodiments.

Embodiment 50. A method for ion exchanging a glass-ceramic article, the method comprising:
contacting at least a first surface of a glass-ceramic article with an ion exchange medium comprising less than 0.03 wt % total of one or more lithium-containing salts; and
forming a first region in the glass-ceramic article extending from the first surface to a first depth d1 during the contacting, wherein a compressive stress layer extending from the first surface to a depth of compression (DOC),
wherein after forming the first region, the glass-ceramic article comprises a second region extending from a depth greater than or equal to d1 to a second depth d2, wherein the second region comprises a crystalline phase and a glass phase and wherein an area percentage of crystals in the first region is less than an area percentage of crystals in the second region.

Embodiment 51. The method of Embodiment 50, wherein the ion exchange medium comprises at least 3 wt % of one or more sodium-containing salts.

Embodiment 52. The method of Embodiment 51, wherein the sodium-containing salt comprises NaNO₃.

Embodiment 53. The method of any one of Embodiments 51 or 52, wherein the ion exchange medium comprises a potassium-containing salt.

Embodiment 54. The method of Embodiment 53, wherein the potassium-containing salt comprises KNO₃.

Embodiment 55. The method of any one of Embodiments 51-54, wherein the ion exchange medium comprises up to 1 wt % NaNO₂.

Embodiment 56. The method of any one of Embodiments 51-55, wherein the ion exchange medium comprises less than 0.02 wt % total of one or more lithium-containing salts.

Embodiment 57. The method of Embodiment 56, wherein the ion exchange medium comprises less than 0.01 wt % total of one or more lithium-containing salts.

Embodiment 58. A method for ion exchanging a glass-ceramic article, the method comprising:
contacting a surface of the glass-ceramic article to a first ion exchange medium comprising at least 0.03 wt % total of one or more lithium-containing salts;
contacting the surface of the glass-ceramic article with a second ion exchange medium after contacting with the first ion exchange medium, wherein the second ion exchange medium comprises a total weight percent of lithium-containing salts less than a total weight percent of lithium-containing salts than the first ion exchange medium; and
forming a first region in the glass-ceramic extending from the first surface to a first depth d1 during the contacting with the second ion exchange medium, and a compressive stress layer extending from the first surface to a depth of compression (DOC),
wherein after forming the first region, the glass-ceramic article comprises a second region extending from a depth greater than or equal to d1 to a second depth d2, wherein the second region comprises a crystalline phase and a glass phase, and wherein an area percentage of crystals in the first region is less than an area percentage of crystals in the second region.

Embodiment 59. The method of Embodiment 58, wherein at least one of the first and second ion exchange mediums comprises at least 3 wt % of one or more sodium-containing salts.

Embodiment 60. The method of Embodiment 59, wherein the sodium-containing salt comprises NaNO₃.

Embodiment 61. The method of any one of Embodiments 58-60, wherein at least one of the first and second ion exchange mediums comprises a potassium-containing salt.

Embodiment 62. The method of Embodiment 61, wherein the potassium-containing salt comprises KNO₃.

Embodiment 63. The method of any one of Embodiments 58-62, wherein at least one of the first and second ion exchange mediums comprises up to 1 wt % NaNO₂.

Embodiment 64. The method of any one of Embodiments 58-63, wherein the first ion exchange medium comprises at least 0.05 wt % total of one or more lithium-containing salts.

Embodiment 65. The method of any one of Embodiments 58-64, wherein the second ion exchange medium comprises less than 0.5 wt % total of one or more lithium-containing salts.

Embodiment 66. The method of any Embodiment 65, wherein the second ion exchange medium comprises less than 0.2 wt % total of one or more lithium-containing salts.

Embodiment 67. The method of any one of Embodiments 58-66, wherein the first ion exchange medium is maintained at higher temperature than the second ion exchange medium.

Embodiment 68. The method of any one of Embodiments 58-67, wherein the glass-ceramic article is contacted with the first ion exchange medium for a longer time than it is contacted with the second ion exchange medium.

Embodiment 69. The method of any one of Embodiments 58-68, wherein the total of one or more lithium-containing salts in the first ion exchange medium is at least 0.01 wt % greater than the total of one or more lithium-containing salts in the second ion exchange medium.

Embodiment 70. The method of any of Embodiments 50-69, wherein a reduced modulus of the first region is less than the reduced modulus of the second region.

Embodiment 71. The method of any of Embodiments 50-70, wherein a hardness of the first region is less than the hardness of the second region.

Embodiment 72. The method of any of Embodiments 50-71, wherein the first surface has an average maximum scratch width of less than 155 microns when subjected to the Scratch Test at load of 5 N based on an average of 15 measurements.

Embodiment 73. The method of any of Embodiments 50-72, wherein the DOC is greater than d1.

Embodiment 74. The method of any of Embodiments 50-71, wherein the DOC is greater than or equal to 0.05 mm, and wherein a maximum compressive stress in the first region is greater than or equal to 50 MPa.

What is claimed is:

1. A method for ion exchanging a glass-ceramic article, the method comprising:
contacting at least a first surface of a glass-ceramic article with an ion exchange medium comprising less than 0.03 wt % total of one or more lithium-containing salts; and
forming a first region in the glass-ceramic article extending from the first surface to a first depth d1 during the contacting, wherein a compressive stress layer extending from the first surface to a depth of compression (DOC),
wherein after forming the first region, the glass-ceramic article comprises a second region extending from a depth greater than or equal to d1 to a second depth d2, wherein the second region comprises a crystalline phase and a glass phase and wherein an area percentage of crystals in the first region is less than an area percentage of crystals in the second region.

2. The method of claim 1, wherein the ion exchange medium comprises at least 3 wt % of one or more sodium-containing salts, and the sodium-containing salt comprises NaNO₃.

3. The method of claim 2, wherein the ion exchange medium comprises a potassium-containing salt, and the potassium-containing salt comprises KNO₃.

4. The method of claim 2, wherein the ion exchange medium comprises up to 1 wt % NaNO₂.

5. The method of claim 2, wherein the ion exchange medium comprises less than 0.02 wt % total of one or more lithium-containing salts.

6. The method of claim 5, wherein the ion exchange medium comprises less than 0.01 wt % total of one or more lithium-containing salts.

7. The method of claim 1, further comprising any one or more of the following:
wherein a reduced modulus of the first region is less than the reduced modulus of the second region;
wherein a hardness of the first region is less than the hardness of the second region; wherein the DOC is greater than d1; or
wherein the DOC is greater than or equal to 0.05 mm, and wherein a maximum compressive stress in the first region is greater than or equal to 50 MPa.

8. A method for ion exchanging a glass-ceramic article, the method comprising:
contacting a surface of the glass-ceramic article to a first ion exchange medium comprising at least 0.03 wt % total of one or more lithium-containing salts;
contacting the surface of the glass-ceramic article with a second ion exchange medium after contacting with the first ion exchange medium, wherein the second ion exchange medium comprises a total weight percent of lithium-containing salts less than a total weight percent of lithium-containing salts than the first ion exchange medium; and
forming a first region in the glass-ceramic extending from the first surface to a first depth d1 during the contacting with the second ion exchange medium, and a compressive stress layer extending from the first surface to a depth of compression (DOC),
wherein after forming the first region, the glass-ceramic article comprises a second region extending from a depth greater than or equal to d1 to a second depth d2, wherein the second region comprises a crystalline phase and a glass phase, and wherein an area percentage of crystals in the first region is less than an area percentage of crystals in the second region.

9. The method of claim 8, wherein at least one of the first and second ion exchange mediums comprises at least 3 wt % of one or more sodium-containing salts.

10. The method of claim 9, wherein the sodium-containing salt comprises NaNO₃.

11. The method of claim 8, wherein at least one of the first and second ion exchange mediums comprises a potassium-containing salt.

12. The method of claim 11, wherein the potassium-containing salt comprises KNO₃.

13. The method of claim 8, wherein at least one of the first and second ion exchange mediums comprises up to 1 wt % NaNO₂.

14. The method of claim 8, wherein the first ion exchange medium comprises at least 0.05 wt % total of one or more lithium-containing salts.

15. The method of claim 8, wherein the second ion exchange medium comprises less than 0.5 wt % total of one or more lithium-containing salts.

16. The method of claim 15, wherein the second ion exchange medium comprises less than 0.2 wt % total of one or more lithium-containing salts.

17. The method of claim 8, wherein the first ion exchange medium is maintained at higher temperature than the second ion exchange medium.

18. The method of claim 8, wherein the glass-ceramic article is contacted with the first ion exchange medium for a longer time than it is contacted with the second ion exchange medium.

19. The method of claim 8, wherein the total of one or more lithium-containing salts in the first ion exchange medium is at least 0.01 wt % greater than the total of one or more lithium-containing salts in the second ion exchange medium.

20. The method of claim 8, further comprising one or more of:
wherein a reduced modulus of the first region is less than the reduced modulus of the second region;
wherein a hardness of the first region is less than the hardness of the second region;
wherein the DOC is greater than d1; or
wherein the DOC is greater than or equal to 0.05 mm, and wherein a maximum compressive stress in the first region is greater than or equal to 50 MPa.
